(19) United States
(12) Patent Application Publication
(10) Pub. No.: US 2024/0373692 A1
(43) Pub. Date: Nov. 7, 2024

(54) DISPLAY DEVICE

(71) Applicant: Samsung Display Co., Ltd., Yongin-Si (KR)

(72) Inventors: Jun Hyun PARK, Yongin-si (KR); Hyeong Seok KIM, Yongin-si (KR); Hee Jean PARK, Yongin-si (KR); Sun Hwa LEE, Yongin-si (KR); Mu Kyung JEON, Yongin-si (KR)

(21) Appl. No.: 18/407,438

(22) Filed: Jan. 9, 2024

(30) Foreign Application Priority Data
May 3, 2023 (KR) 10-2023-0057914

(51) Int. Cl. H10K 59/131; H10K 59/121

(52) U.S. Cl. CPC H10K 59/131; H10K 59/1216

(57) ABSTRACT

The present disclosure relates to a display device, and more particularly, to a display device capable of increasing resolution. According to an embodiment of the disclosure, a substrate; a first gate electrode disposed on the substrate; a lower capacitor electrode disposed on the first gate electrode to overlap the first gate electrode in a plan view; and a repair line disposed on the lower capacitor electrode.

### CROSS-REFERENCE TO RELATED APPLICATION

This application claims priority to Korean Patent Application No. 10-2023-0057914 filed on May 3, 2023, in the Korean Intellectual Property Office, and all the benefits accruing therefrom under 35 U.S.C. 119, the contents of which in its entirety are herein incorporated by reference.

### BACKGROUND

### 1. Technical Field

The present disclosure relates to a display device, and more particularly, to a display device capable of increasing resolution.

### 2. Description of the Related Art

An organic light emitting display device includes a display element of which luminance is changed by current flowing through an organic light emitting diode.

### SUMMARY

Aspects of the present disclosure provide a display device capable of increasing resolution.

The objects of the present disclosure are not limited to those mentioned above and additional objects of the present disclosure, which are not mentioned herein, will be clearly understood by those skilled in the art from the following description of the present disclosure.

According to an embodiment of the disclosure, a display device comprising: a substrate; a first gate electrode disposed on the substrate; a lower capacitor electrode disposed on the first gate electrode to overlap the first gate electrode in a plan view; and a repair line disposed on the lower capacitor electrode.

In an embodiment, the display device may further include an upper capacitor electrode disposed on the lower capacitor electrode to overlap the lower capacitor electrode in a plan view.

In an embodiment, the first gate electrode overlaps the upper capacitor electrode in a plan view.

In an embodiment, an area of the lower capacitor electrode is greater than an area of the first gate electrode in a plan view.

In an embodiment, an area of the upper capacitor electrode is greater than the area of the lower capacitor electrode.

In an embodiment, the display device may further include a driving voltage line connected to the area of the upper capacitor electrode.

In an embodiment, a first capacitor is disposed in an overlapping region between the first gate electrode and the lower capacitor electrode.

In an embodiment, a second capacitor is disposed in an overlapping region between the lower capacitor electrode and the upper capacitor electrode.

In an embodiment, the upper capacitor electrode has a larger number of holes than the lower capacitor electrode.

In an embodiment, one of the holes in the upper capacitor electrode overlaps a hole in the lower capacitor electrode.

In an embodiment, the repair line and the upper capacitor electrode are disposed on the same layer.

In an embodiment, the display device may further include a second gate electrode and a third gate electrode disposed on the same layer as the first gate electrode.

In an embodiment, the display device may further include a second gate electrode disposed adjacent to the first gate electrode and the repair line is disposed between the first gate electrode and the second gate electrode.

In an embodiment, further comprising a pixel connection electrode overlapping the repair line.

In an embodiment, the repair line comprises a repair short portion overlapping the pixel connection electrode.

According to an embodiment of the disclosure, a display device includes a substrate, a first transistor including a first gate electrode disposed on the substrate, a lower capacitor electrode disposed on the first gate electrode to overlap the first gate electrode in a plan view, an upper capacitor electrode disposed on the lower capacitor electrode to overlap the lower capacitor electrode in a plan view, a repair line disposed on a same plane as the upper capacitor electrode, and a pixel electrode disposed on the repair line to overlap the repair line.

In an embodiment, the first gate electrode and the lower capacitor electrode may constitute a first capacitor, and the lower capacitor electrode and the upper capacitor electrode may constitute a second capacitor.

In an embodiment, the first capacitor and the second capacitor may be serially connected between the first gate electrode and a driving voltage line.

In an embodiment, the pixel electrode may include a pixel connection electrode connected to the first transistor, and the repair line may overlap the pixel connection electrode.

In an embodiment, the display device may further include a second transistor including a second gate electrode disposed adjacent to the first gate electrode and the repair line may be disposed between the first gate electrode and the second gate electrode not to overlap the first gate electrode and the second gate electrode in a plan view.

According to the display device of the present disclosure, since a gate electrode and a repair line are disposed on different layers, a distance between the repair line and the gate electrode may be reduced, thereby reducing the size of a pixel. Accordingly, the resolution of the display device may increase.

It should be noted that the effects of the present disclosure are not limited to those described above, and other effects not mentioned will be clearly understood by those skilled in the art from the description below.

### BRIEF DESCRIPTION OF THE DRAWINGS

The above and other aspects and features of the present disclosure will become more apparent by describing in detail exemplary embodiments thereof with reference to the attached drawings, in which:

FIG. 1 is a perspective view showing a display device according to one embodiment;

FIG. 2 is a cross-sectional view illustrating a display device according to one embodiment;

FIG. 3 is a plan view illustrating a display unit of a display device according to one embodiment;

FIG. 4 is a block diagram illustrating a display panel and a display driver according to one embodiment;

FIG. 5 is a circuit diagram of one pixel of a display device according to one embodiment;

FIG. 6 is a plan view of a unit pixel array according to one embodiment;

FIG. 7 is a plan view selectively showing only first and second pattern layers of the components of FIG. 6;

FIG. 8 is a plan view selectively showing only a third pattern layer of the components of FIG. 6;

FIG. 9 is a plan view selectively showing only first to third pattern layers of the components of FIG. 6;

FIG. 10 is a plan view selectively showing only a fourth pattern layer of the components of FIG. 6;

FIG. 11 is a plan view selectively showing only first to fourth pattern layers of the components of FIG. 6;

FIG. 12 is a plan view selectively showing only a fifth pattern layer of the components of FIG. 6;

FIG. 13 is a plan view selectively showing only a sixth pattern layer of the components of FIG. 6;

FIG. 14 is a plan view selectively showing only first to fifth pattern layers of the components of FIG. 6;

FIG. 15 is a plan view selectively showing only fifth and sixth pattern layers of the components of FIG. 6;

FIG. 16 is a plan view selectively showing only sixth and seventh pattern layers of the components of FIG. 6;

FIG. 17 is a cross-sectional view taken along line I-I′ of FIG. 6;

FIG. 18 is a cross-sectional view taken along line II-II′ of FIG. 6;

FIG. 19 is a circuit diagram of one pixel of a display device according to one embodiment;

FIG. 20 is a plan view of a unit pixel array according to one embodiment;

FIG. 21 is a plan view selectively showing only first and second pattern layers of the components of FIG. 20;

FIG. 22 is a plan view selectively showing only a third pattern layer of the components of FIG. 20;

FIG. 23 is a plan view selectively showing only first to fourth pattern layers of the components of FIG. 20;

FIG. 24 is a plan view selectively showing only a fifth pattern layer of the components of FIG. 20;

FIG. 25 is a plan view selectively showing only a sixth pattern layer of the components of FIG. 20;

FIG. 26 is a plan view selectively showing only first to fifth pattern layers of the components of FIG. 20;

FIG. 27 is a plan view selectively showing only fifth and sixth pattern layers of the components of FIG. 20;

FIG. 28 is a plan view selectively showing only sixth and seventh pattern layers of the components of FIG. 20;

FIG. 29 is a cross-sectional view taken along line III-III′ of FIG. 20;

FIG. 30 is a cross-sectional view illustrating a structure of a display element according to one embodiment;

FIGS. 31, 32, 33 and 34 are cross-sectional views illustrating a structure of the light emitting element LEL according to one embodiment;

FIG. 35 is a cross-sectional view illustrating an example of the organic light emitting diode of FIG. 33;

FIG. 36 is a cross-sectional view illustrating an example of the organic light emitting diode of FIG. 34; and

FIG. 37 is a cross-sectional view illustrating a structure of a pixel of a display device according to one embodiment.

### DETAILED DESCRIPTION OF THE EMBODIMENTS

Advantages and features of the present disclosure and methods of achieving the same will become apparent with reference to the exemplary embodiments described below in detail in conjunction with the accompanying drawings. However, the present disclosure is not limited to exemplary embodiments to be described below, but may be implemented in various different forms, the present exemplary embodiments will be provided only in order to make the present disclosure complete and allow one of ordinary skill in the art to which the present disclosure pertains to completely recognize the scope of the present disclosure, and the present disclosure will be defined by the scope of the claims.

When an element or layer is referred to as being “on” another element or layer, it includes both a case in which the element or layer is directly on another element or layer and a case in which the element or layer is on another element or layer with the other element or layer interposed therebetween. The same reference numbers indicate the same components throughout the specification. Shapes, sizes, proportions, angles, numbers, and the like, disclosed in the drawings for describing exemplary embodiments are examples, and thus, the present disclosure is not limited to those illustrated in the drawings.

It will be understood that, although the terms “first”, “second”, and the like may be used to describe various components, these components should not be limited by these terms. These terms are only used to distinguish one component from another component. Accordingly, a first component discussed below could be termed a second component without departing from the teachings of the present disclosure.

Each feature of the various exemplary embodiments of the present disclosure may be partially or entirely coupled or combined with each other, and is technically capable of various interlocking and driving, and each exemplary embodiment may be implemented independently of each other or may be implemented together in an association relationship.

In the specification, “A and/or B” represents the case of A, B, or A and B. In addition, in the specification, “at least one of A and B” represents the case of A, B, or A and B. Hereinafter, embodiments will be described in detail with reference to the accompanying drawings.

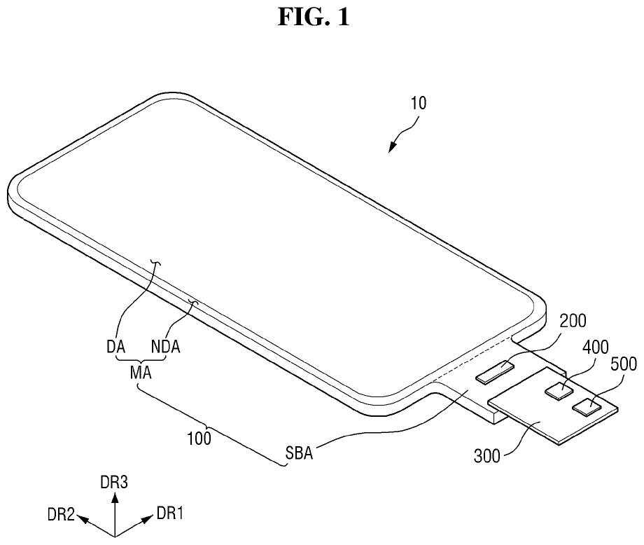

FIG. 1 is a perspective view showing a display device according to one embodiment.

Referring to FIG. 1, a display device 10 may be applied to portable electronic devices such as a mobile phone, a smartphone, a tablet personal computer, a mobile communication terminal, an electronic organizer, an electronic book, a portable multimedia player (PMP), a navigation system, an ultra mobile PC (UMPC) or the like. For example, the display device 10 may be applied as a display unit of a television, a laptop, a monitor, a billboard, or an Internet-of-Things (IoT) device. For another example, the display device 10 may be applied to wearable devices such as a smart watch, a watch phone, a glasses type display, or a head mounted display (HMD).

The display device 10 may have a planar shape similar to a quadrilateral shape. For example, the display device 10 may have a planar shape similar to a quadrilateral shape having a short side in the first direction DR1 and a long side in the second direction DR2. A corner where the short side in the first direction DR1 and the long side in the second direction DR2 meet may be right-angled or rounded with a predetermined curvature. The planar shape of the display device 10 is not limited to a quadrilateral shape, and may be formed in a shape similar to another polygonal shape, a circular shape, or elliptical shape.

The display device 10 may include a display panel 100, a display driver 200, a circuit board 300, a touch driver 400, and a power supply unit 500.

The display panel 100 may include a main region MA and a sub-region SBA.

The main region MA may include the display area DA including pixels displaying an image and the non-display area NDA disposed around the display area DA. The display area DA may emit light from a plurality of emission areas or a plurality of opening areas. For example, the display panel 100 may include a pixel circuit including switching elements, a pixel defining layer defining an emission area or an opening area, and a self-light emitting element.

For example, the self-light emitting element may include at least one of an organic light emitting diode (LED) including an organic light emitting layer, a quantum dot LED including a quantum dot light emitting layer, an inorganic LED including an inorganic semiconductor, or a micro LED, but is not limited thereto.

The non-display area NDA may be an area surrounding the display area DA. The non-display area NDA may be defined as an edge area of the main region MA of the display panel 100. The non-display area NDA may include a gate driver (not illustrated) that supplies gate signals to the gate lines, and fan-out lines (not illustrated) that connect the display driver 200 to the display area DA.

The sub-region SBA may extend from one side of the main region MA. The sub-region SBA may include a flexible material which can be bent, folded or rolled. For example, when the sub-region SBA is bent, the sub-region SBA may overlap the main region MA in a thickness direction (e.g., a third direction DR3). The sub-region SBA may include the display driver 200 and a pad portion connected to the circuit board 300. Optionally, the sub-region SBA may be omitted, and the display driver 200 and the pad portion may be arranged in the non-display area NDA.

The display driver 200 may output signals and voltages for driving the display panel 100. The display driver 200 may supply data voltages to data lines. The display driver 200 may supply a power voltage to the power line and may supply a gate control signal to the gate driver. The display driver 200 may be formed as an integrated circuit (IC) and mounted on the display panel 100 by a chip on glass (COG) method, a chip on plastic (COP) method, or an ultrasonic bonding method. For example, the display driver 200 may be disposed in the sub-region SBA, and may overlap the main region MA in the thickness direction (third direction DR3) by bending of the sub-region SBA. For another example, the display driver 200 may be mounted on the circuit board 300.

The circuit board 300 may be attached to the pad portion of the display panel 100 by using an anisotropic conductive film (ACF). Lead lines of the circuit board 300 may be electrically connected to a pad portion of the display panel 100. The circuit board 300 may be a flexible printed circuit board, a printed circuit board, or a flexible film such as a chip on film.

A touch driver 400 may be mounted on the circuit board 300. The touch driver 400 may be electrically connected to a touch sensing unit of the display panel 100. The touch driver 400 may supply a touch driving signal to a plurality of touch electrodes of the touch sensing unit and may sense an amount of change in capacitance between the plurality of touch electrodes. For example, the touch driving signal may be a pulse signal having a predetermined frequency. The touch driver 400 may calculate whether an input is made and input coordinates based on an amount of change in capacitance between the plurality of touch electrodes. The touch driver 400 may be formed of an integrated circuit (IC).

The power supply unit 500 may be disposed on the circuit board 300 to supply a power voltage to the display driver 200 and the display panel 100. The power supply unit 500 may generate a driving voltage to supply it to a driving voltage line VDL, generate an initialization voltage (e.g., a first initialization voltage and a second initialization voltage) to supply it to an initialization voltage line (e.g., a first initialization voltage line VIL1 and a second initialization voltage line VIL2), and generate a common voltage to supply it to a common electrode which is common to light emitting elements of the plurality of pixels. For example, the driving voltage may be a high potential voltage for driving the light emitting element, and the common voltage may be a low potential voltage for driving the light emitting element.

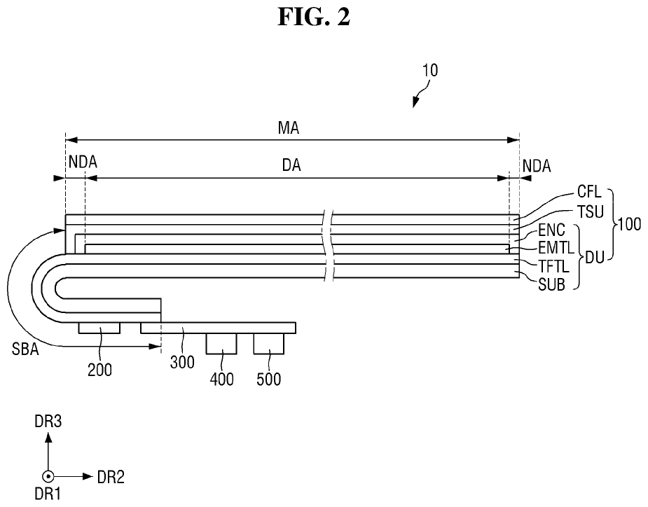

FIG. 2 is a cross-sectional view illustrating a display device according to one embodiment.

Referring to FIG. 2, the display panel 100 may include a display unit DU, a touch sensing unit TSU, and a color filter layer CFL. The display unit DU may include a substrate SUB, a thin film transistor layer TFTL, a light emitting element layer EMTL, and an encapsulation layer TFEL.

The substrate SUB may be a base substrate or a base member. The substrate SUB may be a flexible substrate which can be bent, folded or rolled. For example, the substrate SUB may include a polymer resin such as polyimide (PI), but is not limited thereto. For another example, the substrate SUB may include a glass material or a metal material.

The thin film transistor layer TFTL may be disposed on the substrate SUB. The thin film transistor layer TFTL may include a plurality of thin film transistors constituting a pixel circuit of pixels. The thin film transistor layer TFTL may further include gate lines, data lines, power lines, gate control lines, fan-out lines that connect the display driver 200 to the data lines, and lead lines that connect the display driver 200 to the pad portion. Each of the thin film transistors may include a semiconductor region, a source electrode, a drain electrode, and a gate electrode. For example, when the gate driver is formed on one side of the non-display area NDA of the display panel 100, the gate driver may include thin film transistors.

The thin film transistor layer TFTL may be disposed in the display area DA, the non-display area NDA, and the sub-region SBA. Thin film transistors, gate lines, data lines, and power lines of each of the pixels of the thin film transistor layer TFTL may be disposed in the display area DA. Gate control lines and fan-out lines of the thin film transistor layer TFTL may be disposed in the non-display area NDA. The lead lines of the thin film transistor layer TFTL may be disposed in the sub-region SBA.

The light emitting element layer EMTL may be disposed on the thin film transistor layer TFTL. The light emitting element layer EMTL may include a plurality of light emitting elements each of which a pixel electrode, a light emitting layer, and a common electrode are sequentially stacked to emit light, and a pixel defining layer defining pixels. The plurality of light emitting elements of the light emitting element layer EMTL may be disposed in the display area DA.

For example, the light emitting layer may be an organic light emitting layer including an organic material. The light emitting layer may include a hole transporting layer, an organic light emitting layer, and an electron transporting layer. When the pixel electrode receives a predetermined voltage through the thin film transistor of the thin film transistor layer TFTL and the common electrode receives the cathode voltage, holes and electrons may be transferred to the organic light emitting layer through the hole transporting layer and the electron transporting layer, respectively and may be combined with each other to emit light in the organic light emitting layer. For example, the pixel electrode may be an anode electrode, and the common electrode may be a cathode electrode, but the present disclosure is not limited thereto.

For another example, the plurality of light emitting elements may include a quantum dot light emitting diode including a quantum dot light emitting layer, an inorganic light emitting diode including an inorganic semiconductor, or a micro light emitting diode.

The encapsulation layer ENC may cover the top surface and the side surface of the light emitting element layer EMTL, and may protect the light emitting element layer EMTL. The encapsulation layer ENC may include at least one inorganic layer and at least one organic layer for encapsulating the light emitting element layer EMTL.

The touch sensing unit TSU may be disposed on the encapsulation layer ENC. The touch sensing unit TSU may include a plurality of touch electrodes for sensing a user's touch in a capacitive manner, and touch lines connecting the plurality of touch electrodes to the touch driver 400. For example, the touch sensing unit TSU may sense the user's touch by using a mutual capacitance method or a self-capacitance method.

For another example, the touch sensing unit TSU may be disposed on a separate substrate disposed on the display unit DU. In this case, the substrate supporting the touch sensing unit TSU may be a base member that encapsulates the display unit DU.

The plurality of touch electrodes of the touch sensing unit TSU may be disposed in a touch sensor area overlapping the display area DA. The touch lines of the touch sensing unit TSU may be disposed in a touch peripheral area that overlaps the non-display area NDA.

The color filter layer CFL may be disposed on the touch sensing unit TSU. The color filter layer CFL may include a plurality of color filters respectively corresponding to the plurality of emission areas. Each of the color filters may selectively transmit light of a specific wavelength and may block or absorb light of a different wavelength. The color filter layer CFL may absorb a part of light coming from the outside of the display device 10 to reduce reflected light due to external light. Accordingly, the color filter layer CFL may prevent color distortion caused by reflection of the external light.

Since the color filter layer CFL is directly disposed on the touch sensing unit TSU, the display device 10 may not require a separate substrate for the color filter layer CFL. Therefore, the thickness of the display device 10 may be relatively reduced.

The sub-region SBA of the display panel 100 may extend from one side of the main region MA. The sub-region SBA may include a flexible material which can be bent, folded or rolled. For example, when the sub-region SBA is bent, the sub-region SBA may overlap the main region MA in a thickness direction (third direction DR3). The sub-region SBA may include the display driver 200 and the pad portion electrically connected to the circuit board 300.

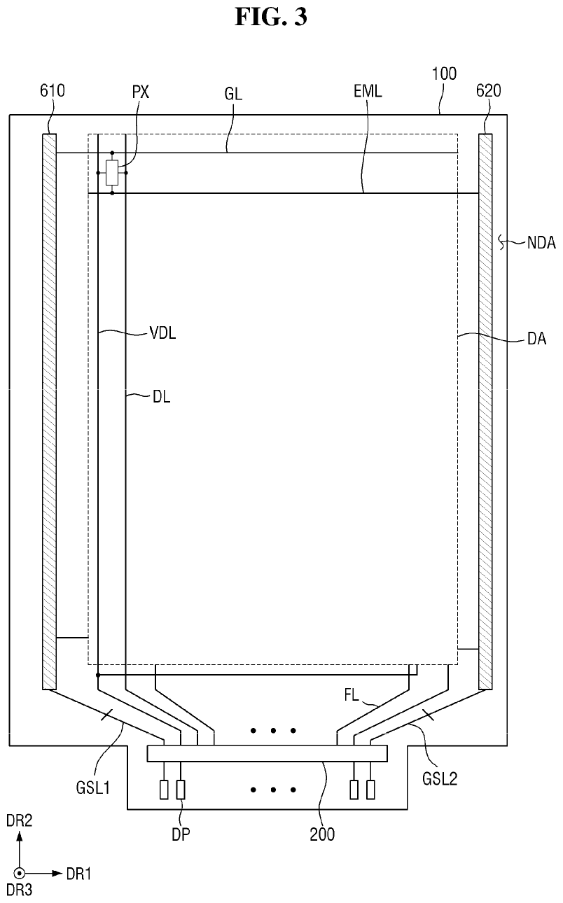

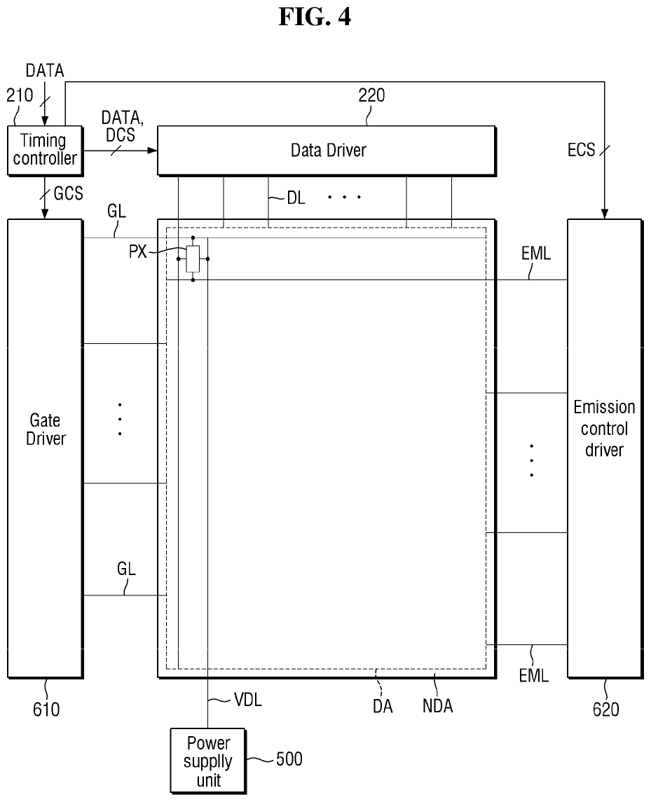

FIG. 3 is a plan view illustrating a display unit of a display device according to one embodiment. FIG. 4 is a block diagram illustrating a display panel and a display driver according to one embodiment.

Referring to FIGS. 3 and 4, the display panel 100 may include the display area DA and the non-display area NDA.

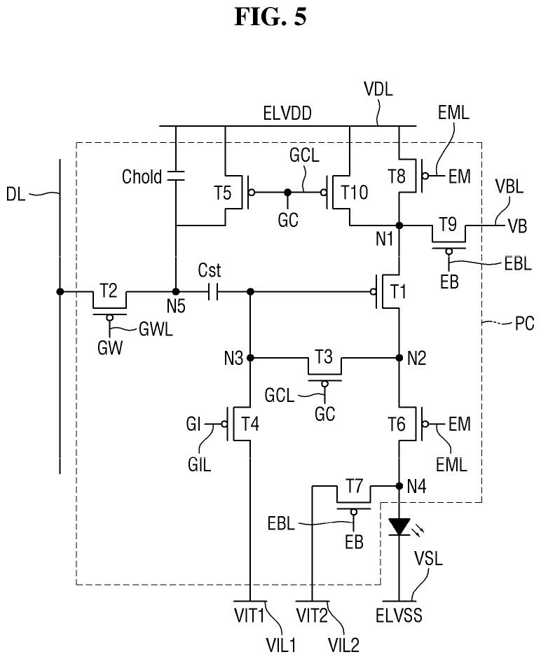

The display area DA may include a plurality of pixels PX, and a plurality of driving voltage lines VDL, a plurality of common voltage lines VSL (see FIG. 5), a plurality of gate lines GL, a plurality of emission control lines EML, and a plurality of data lines DL connected to the plurality of pixels PX.

Each of the plurality of pixels PX may be connected to the gate line GL, the data line DL, the emission control line EML, the driving voltage line VDL, and the common voltage line VSL. Each of the pixels PX may include at least one transistor, a light emitting element and a capacitor.

Each of the plurality of gate lines GL may extend in the first direction DR1 and may be spaced apart from each other in the second direction DR2 intersecting the first direction DR1. The gate lines GL may be arranged along the second direction DR2. The gate lines GL may sequentially supply gate signals to the plurality of pixels PX.

The emission control lines EML may extend in the first direction DR1 and may be spaced apart from each other in the second direction DR2. The emission control line EML may be arranged along the second direction DR2. The emission control lines EML may sequentially supply an emission control signal to the plurality of pixels PX.

The data lines DL may extend in the second direction DR2 and may be spaced apart from each other in the first direction DR1. The data lines DL may be arranged along the first direction DR1. The data lines DL may supply data voltages to the plurality of pixels PX. The data voltage may determine the luminance of each of the pixels PX.

The driving voltage lines VDL may extend in the second direction DR2 and may be spaced apart from each other in the first direction DR1. The driving voltage lines VDL may be arranged along the first direction DR1. The driving voltage lines VDL may supply a first driving voltage to the plurality of pixels PX. The first driving voltage may be a high potential voltage for driving the light emitting elements of the pixels PX.

The non-display area NDA may surround the display area DA. The non-display area NDA may include a gate driver 610, an emission control driver 620, fan-out lines FL, a first gate control line GSL1, and a second gate control line GSL2.

The fan-out lines FL may extend from the display driver 200 to the display area DA. The fan-out lines FL may supply the data voltage received from the display driver 200 to the plurality of data lines DL.

The first gate control line GSL1 may extend from the display driver 200 to the gate driver 610. The first gate control line GSL1 may supply a gate control signal GCS received from the display driver 200 to the gate driver 610.

The second gate control line GSL2 may extend from the display driver 200 to the emission control driver 620. The second gate control line GSL2 may supply an emission control signal ECS received from the display driver 200 to the emission control driver 620.

The sub-region SBA may extend from one side of the non-display area NDA. The sub-region SBA may include the display driver 200 and the pad portion DP. The pad portion DP may be disposed closer to one edge of the sub-region SBA than the display driver 200. The pad portion DP may be electrically connected to the circuit board 300 through an anisotropic conductive film ACF.

The display driver 200 may include a timing controller 210 and a data driver 220.

The timing controller 210 may receive digital video data DATA and timing signals from the circuit board 300. The timing controller 210 may generate, based on the timing signals, a data control signal DCS to control the operation timing of the data driver 220, the gate control signal GCS to control the operation timing of the gate driver 610, and the emission control signal ECS to control the operation timing of the emission control driver 620. The timing controller 210 may supply the gate control signal GCS to the gate driver 610 through the first gate control line GSL1. The timing controller 210 may supply the emission control signal ECS to the emission control driver 620 through the second gate control line GSL2. The timing controller 210 may supply the digital video data DATA and the data control signal DCS to the data driver 220.

The data driver 220 may convert the digital video data DATA into analog data voltages and supply them to the data lines DL through the fan-out lines FL. The gate signals of the gate driver 610 may select the pixels PX to which the data voltage is supplied, and the selected pixels PX may receive the data voltage through the data lines DL.

The power supply unit 500 may be disposed on the circuit board 300 to supply a power voltage to the display driver 200 and the display panel 100. The power supply unit 500 may generate and supply a driving voltage to the driving voltage line VDL, generate and supply an initialization voltage to the initialization voltage line, and generate and supply a common voltage to the common electrode common to the light emitting elements of the plurality of pixels.

The gate driver 610 may be disposed at one external side of the display area DA or at one side of the non-display area NDA. The emission control driver 620 may be disposed at the other external side of the display area DA or at the other side of the non-display area NDA. However, the present disclosure is not limited thereto. As another example, the gate driver 610 and the emission control driver 620 may be disposed at any one of one side and the other side of the non-display area NDA.

The gate driver 610 may include a plurality of transistors for generating gate signals based on the gate control signal GCS. The emission control driver 620 may include a plurality of transistors for generating emission control signals based on the emission control signal ECS. For example, the transistors of the gate driver 610 and the transistors of the emission control driver 620 may be formed on the same layer as the transistors of each of the pixels PX. The gate driver 610 may supply the gate signals to the gate lines GL, and the emission control driver 620 may supply the emission control signals to the emission control lines EML.

FIG. 5 is a circuit diagram of one pixel of a display device according to one embodiment.

The pixel SP may be connected to a first gate line GWL, a second gate line GCL, a third gate line GIL, a fourth gate line EBL, the emission control line EML, the data line DL, the driving voltage line VDL, a common voltage line VSL, a first initialization voltage line VIL1, a second initialization voltage line VIL2, and a bias voltage line VBL.

The pixel (e.g., PX) may include a pixel circuit PC and a light emitting element ED. The pixel circuit PC may include a first transistor T1, a second transistor T2, a third transistor T3, a fourth transistor T4, a fifth transistor T5, a sixth transistor T6, and a seventh transistor T7, an eighth transistor T8, a ninth transistor T9, a tenth transistor T10, a first capacitor Cst, and a second capacitor Chold.

The first transistor T1 may include a gate electrode, a source electrode, and a drain electrode. The first transistor T1 may control a source-drain current (hereinafter, a driving current) according to the data voltage applied to the gate electrode. The driving current (e.g., Isd) flowing through a channel region of the first transistor T1 may be proportional to the square of a difference between the threshold voltage Vth and the voltage Vsg between the source electrode and the gate electrode of the first transistor T1 (Isd=k×(Vsg−Vth)²). Here, k is a proportional coefficient determined by the structure and physical characteristics of the first transistor T1, Vsg is a source-gate voltage of the first transistor ST1, and Vth is a threshold voltage of the first transistor T1.

The light emitting element ED may emit light by receiving the driving current Isd. The emission amount or the luminance of the light emitting element ED may be proportional to the magnitude of the driving current Isd.

The light emitting element ED may be an organic light emitting diode including a first electrode, a second electrode, and an organic light emitting layer disposed between the first electrode and the second electrode. For another example, the light emitting element ED may be an inorganic light emitting element including a first electrode, a second electrode, and an inorganic semiconductor disposed between the first electrode and the second electrode. For still another example, the light emitting element ED may be a quantum dot light emitting element including a first electrode, a second electrode, and a quantum dot light emitting layer disposed between the first electrode and the second electrode. For still another example, the light emitting element ED may be a micro light emitting diode.

The first electrode of the light emitting element ED may be electrically connected to a fourth node N4. The first electrode of the light emitting element ED may be connected to the drain electrode of the sixth transistor T6 and the source electrode of the seventh transistor T7 through the fourth node N4. The second electrode of the light emitting element ED may be connected to the common voltage line VSL. The second electrode of the light emitting element ED may receive a common voltage VS (e.g., low potential voltage) from the common voltage line VSL.

The second transistor T2 may be turned on by a first gate signal GW of the first gate line GWL to electrically connect the data line DL with a fifth node N5. The drain electrode of the second transistor T2, the first electrode of the first capacitor Cst, the first electrode of the second capacitor Chold, and the drain electrode of the fifth transistor T5 may be connected to the fifth node N5. The second transistor T2 may be turned on in response to the first gate signal GW to supply the data voltage to the fifth node N5. The gate electrode of the second transistor T2 may be electrically connected to the first gate line GWL, the source electrode thereof may be electrically connected to the data line DL, and the drain electrode thereof may be electrically connected to the fifth node N5. Meanwhile, the second transistor T2 may be configured as a dual gate transistor. For example, the second transistor T2 may include a second-first transistor and a second-second transistor connected in series between the data line DL and the fifth node N5. The gate electrode of the second-first transistor may be electrically connected to the first gate line GWL, the source electrode thereof may be electrically connected to the data line DL, and the drain electrode thereof may be electrically connected to the source electrode of the second-second transistor. The gate electrode of the second-second transistor may be electrically connected to the first gate line GWL, the source electrode thereof may be electrically connected to the drain electrode of the second-first transistor, and the drain electrode thereof may be electrically connected to the fifth node N5.

The third transistor T3 may be turned on by a second gate signal GC of the second gate line GCL to electrically connect a third node N3 to a second node N2. For example, the gate electrode of the third transistor T3 may be electrically connected to the second gate line GCL, the source electrode thereof may be electrically connected to the third node N3, and the drain electrode thereof may be electrically connected to the second node N2. The source electrode of the third transistor T3, the second electrode of the first capacitor Cst, and the gate electrode of the first transistor T1 may be connected to the third node N3. The drain electrode of the third transistor T3, the drain electrode of the first transistor T1, and the drain electrode of the sixth transistor T6 may be connected to the second node N2. The third transistor T3 may be turned on by the second gate signal GC of the second gate line GCL to electrically connect the second node N2 to the third node N3.

The fourth transistor T4 may be turned on by a third gate signal GI of the third gate line GIL to electrically connect the third node N3 to the first initialization voltage line VIL1. The fourth transistor T4 may be connected between the third node N3 and the first initialization voltage line VIL1. For example, the gate electrode of the fourth transistor T4 may be electrically connected to the third gate line GIL, the source electrode thereof may be electrically connected to the third node N3, and the drain electrode thereof may be electrically connected to the first initialization voltage line VIL1. Meanwhile, the fourth transistor T4 may be configured as a dual gate transistor. For example, the fourth transistor T4 may include a fourth-first transistor and a fourth-second transistor connected in series. The gate electrode of the fourth-first transistor may be electrically connected to the third gate line GIL, the drain electrode thereof may be electrically connected to the first initialization voltage line VIL1, and the source electrode thereof may be connected to the drain electrode of the fourth-second transistor. The gate electrode of the fourth-second transistor may be electrically connected to the third gate line GIL, the drain electrode thereof may be connected to the source electrode of the fourth-first transistor, and the source electrode thereof may be electrically connected to the third node N3.

The fifth transistor T5 may be turned on by the second gate signal GC of the second gate line GCL to electrically connect the driving voltage line VDL to the fifth node N5. For example, the gate electrode of the fifth transistor T5 may be electrically connected to the second gate line GCL, the source electrode thereof may be connected to the driving voltage line VDL, and the drain electrode thereof may be electrically connected to the fifth node N5. The fifth transistor T5 may be turned on by the second gate signal GC of the second gate line GCL to electrically connect the driving voltage line VDL to the fifth node N5. Meanwhile, the fifth transistor T5 may be configured as a dual gate transistor. For example, the fifth transistor T5 may include a fifth-first transistor and a fifth-second transistor connected in series. The gate electrode of the fifth-first transistor may be electrically connected to the second gate line GCL, the source electrode thereof may be connected to the driving voltage line VDL, and the drain electrode thereof may be electrically connected to the source electrode of the fifth-second transistor. The gate electrode of the fifth-second transistor may be electrically connected to the second gate line GCL, the source electrode thereof may be connected to the drain electrode of the fifth-first transistor, and the drain electrode thereof may be electrically connected to the fifth node N5.

The sixth transistor T6 may be turned on by an emission control signal EM of the emission control line EML to electrically connect the second node N2 to the fourth node N4, which is the first electrode of the light emitting element ED. The gate electrode of the sixth transistor T6 may be electrically connected to the emission control line EML, the source electrode thereof may be electrically connected to the second node N2, and the drain electrode thereof may be electrically connected to the fourth node N4.

The seventh transistor T7 may be turned on by a fourth gate signal EB of the fourth gate line EBL to electrically connect the fourth node N4 that is the first electrode of the light emitting element ED with the second initialization voltage line VIL2. By turning on the seventh transistor T7 in response to the fourth gate signal, the first electrode of the light emitting element ED may be discharged to a second initialization voltage VI2. The gate electrode of the seventh transistor T7 may be electrically connected to the fourth gate line EBL, the source electrode thereof may be electrically connected to the fourth node N4, and the drain electrode thereof may be electrically connected to the second initialization voltage line VIL2. The second initialization voltage line VIL2 may transmit a second initialization voltage VI2.

The eighth transistor T8 may be turned on by an emission control signal EM of the emission control line EML to electrically connect the driving voltage line VDL with the first node N1. The gate electrode of the eighth transistor T8 may be electrically connected to the emission control line EML, the source electrode thereof may be electrically connected to the driving voltage line VDL, and the drain electrode thereof may be electrically connected to the first node N1. The drain electrode of the eighth transistor T8, the source electrode of the first transistor T1, the drain electrode of the ninth transistor T9, and the drain electrode of the tenth transistor T10 may be connected to the first node N1.

The ninth transistor T9 may be turned on by the fourth gate signal EB of the fourth gate line EBL to electrically connect the bias voltage line VBL to the first node N1. The ninth transistor T9 may be turned on according to the fourth gate signal EB to supply a bias voltage VB to the first node N1. The ninth transistor T9 may improve hysteresis of the first transistor T1 by supplying the bias voltage VB to the source electrode of the first transistor T1 connected to the first node N1. The gate electrode of the ninth transistor T9 may be electrically connected to the fourth gate line EBL, the source electrode thereof may be electrically connected to the bias voltage line VBL, and the drain electrode thereof may be electrically connected to the first node N1.

The tenth transistor T10 may be turned on by the second gate signal GC of the second gate line GCL to electrically connect the driving voltage line VDL to the first node N1. For example, the gate electrode of the tenth transistor T10 may be electrically connected to the second gate line GCL, the source electrode thereof may be connected to the driving voltage line VDL, and the drain electrode thereof may be electrically connected to the first node N1. The tenth transistor T10 may be turned on by the second gate signal GC of the second gate line GCL to electrically connect the driving voltage line VDL to the first node N1. When all of the eighth transistor T8, the first transistor T1, and the sixth transistor T6 are turned on, the driving current may be supplied to the light emitting element ED.

Each of the first to tenth transistors T1 to T10 may include a silicon-based active layer. For example, each of the first to tenth transistors T1 to T10 may be a p-type transistor including an active layer made of low temperature polycrystalline silicon (LTPS). The active layer made of low temperature polycrystalline silicon may have high electron mobility and excellent turn-on characteristics. Accordingly, in the display device 10, since the transistors having excellent turn-on characteristics are included, it is possible to stably and efficiently drive the plurality of pixels PX. Each of the first to tenth transistors T1 to T10 may output a current flowing from the source electrode to the drain electrode in response to a gate low voltage applied to the gate electrode of the corresponding transistor.

Alternatively, some of the first to tenth transistors T1 to T10 described above may be p-type transistors including an active layer made of low temperature polycrystalline silicon (LTPS) described above, while the others of the first to tenth transistors T1 to T10 may be n-type transistors including an oxide-based active layer. The transistor including the oxide-based active layer may have a coplanar structure in which a gate electrode is disposed thereon. The transistor including the oxide-based active layer may output a current flowing from the drain electrode to the source electrode in response to a gate high voltage applied to the gate electrode.

The first capacitor Cst may be electrically connected between the fifth node N5 and the third node N3. For example, the first electrode of the first capacitor Cst may be electrically connected to the fifth node N5, and the second electrode of the first capacitor Cst may be electrically connected to the third node N3. The first capacitor Cst may maintain the data voltage supplied from the data line DL through the second transistor T2 for one frame period.

The second capacitor Chold may be electrically connected between the driving voltage line VDL and the fifth node N5. For example, the first electrode of the second capacitor Chold may be electrically connected to the fifth node N5, and the second electrode of the second capacitor Chold may be electrically connected to the driving voltage line VDL. The second capacitor Chold may maintain a potential difference between the driving voltage line VDL and the gate electrode of the first transistor T1.

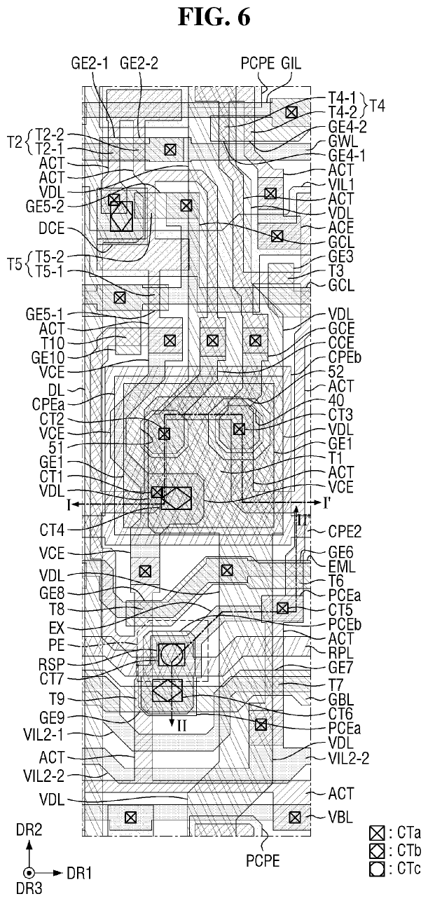

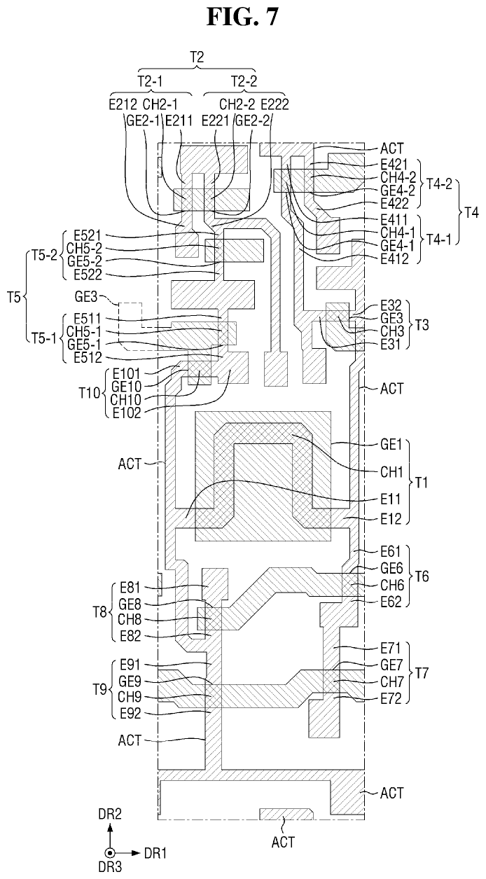

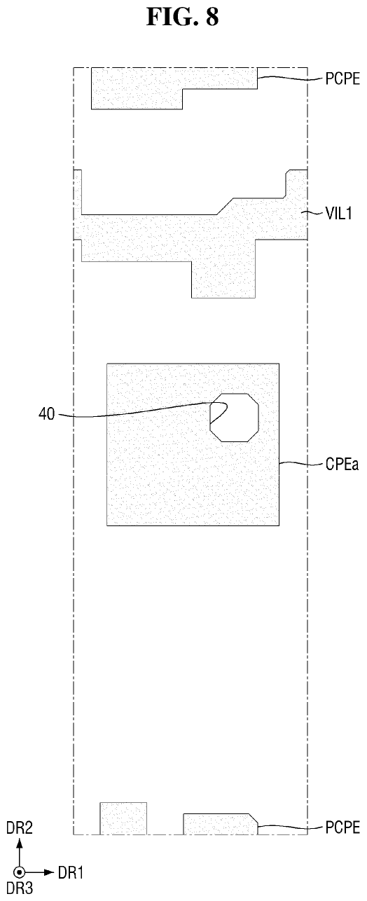

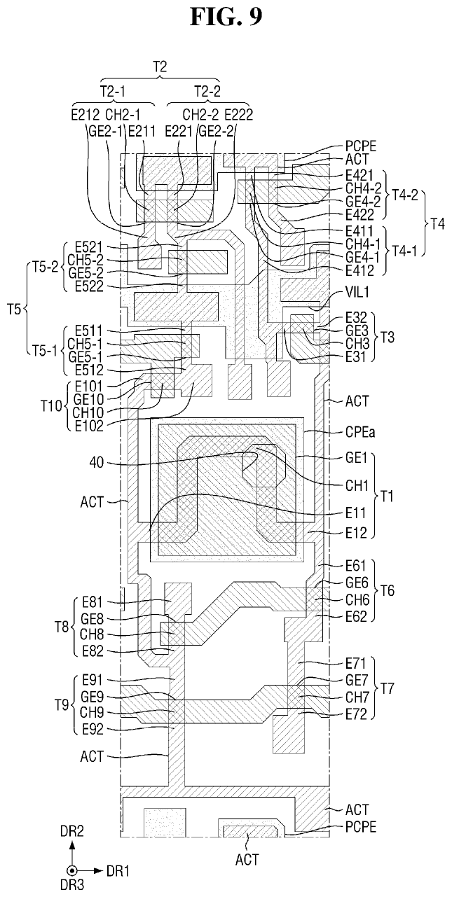

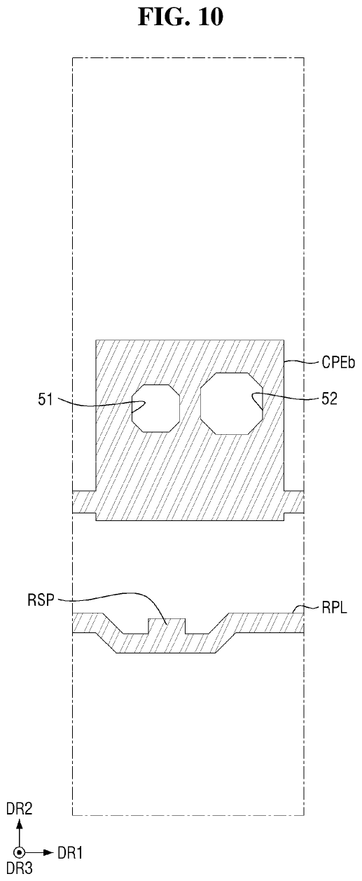

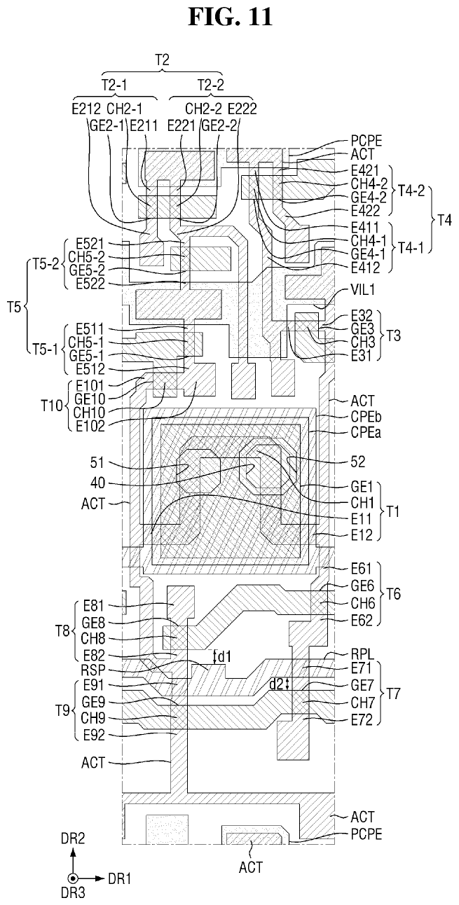

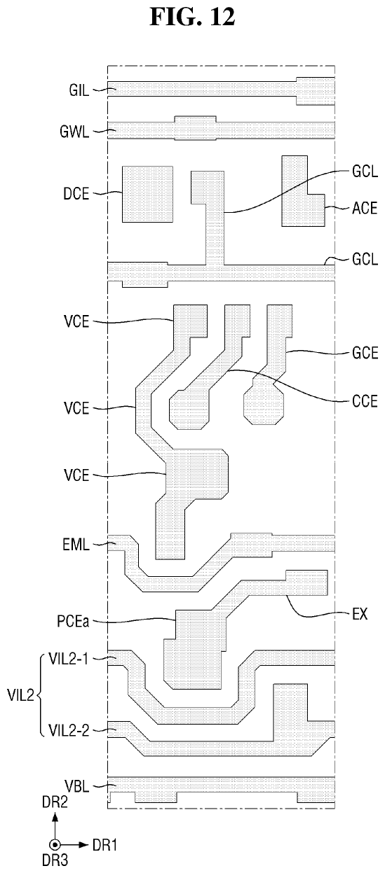

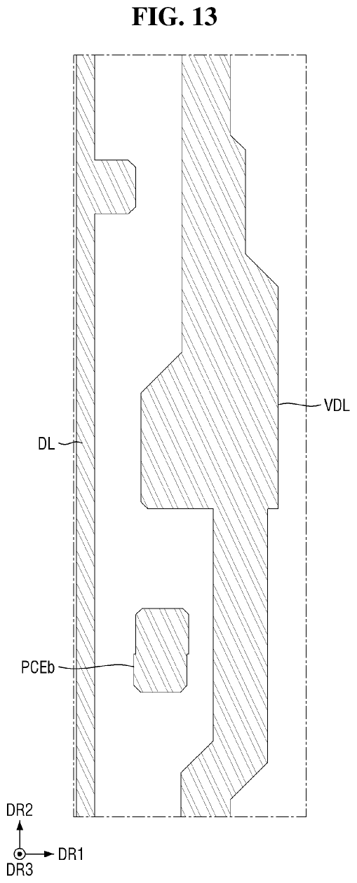

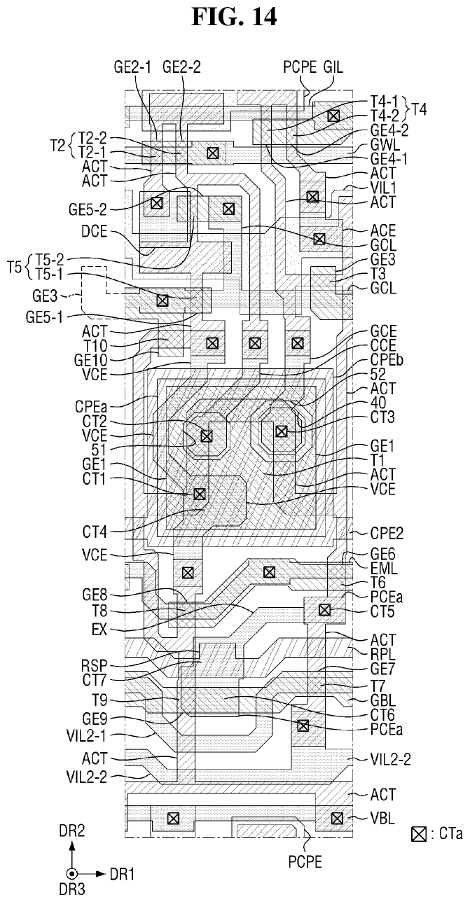

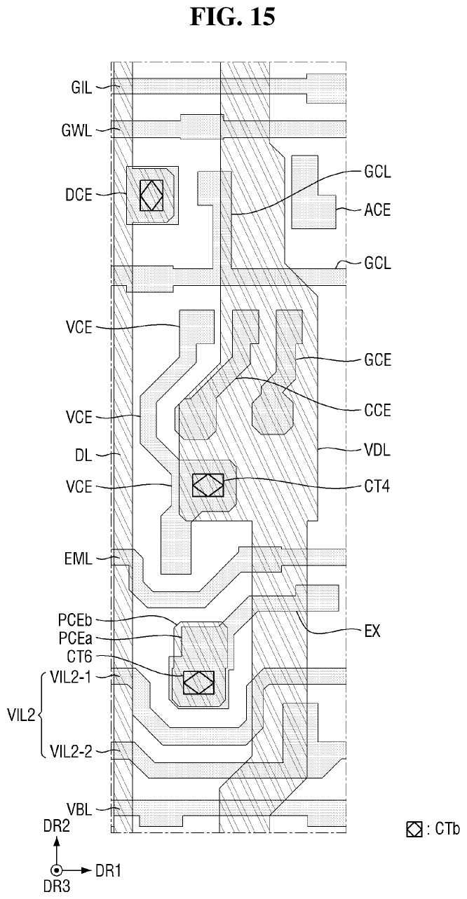

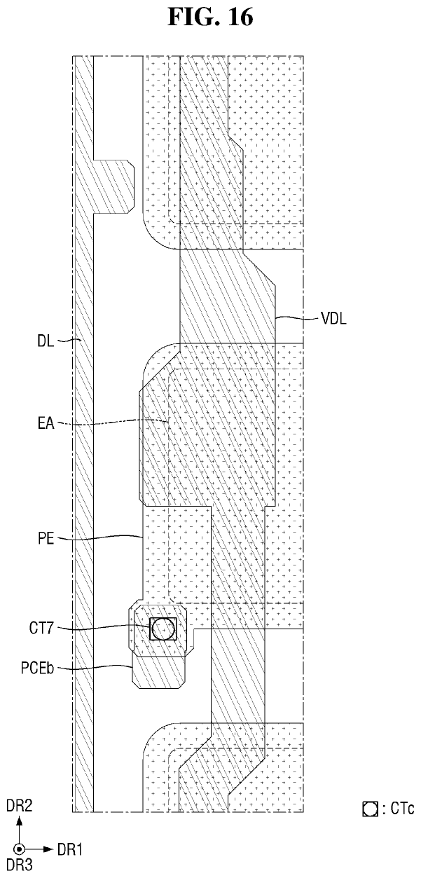

FIG. 6 is a plan view of a unit pixel array according to one embodiment. FIG. 7 is a plan view selectively showing only first and second pattern layers of the components of FIG. 6. FIG. 8 is a plan view selectively showing only a third pattern layer of the components of FIG. 6. FIG. 9 is a plan view selectively showing only first to third pattern layers of the components of FIG. 6. FIG. 10 is a plan view selectively showing only a fourth pattern layer of the components of FIG. 6. FIG. 11 is a plan view selectively showing only first to fourth pattern layers of the components of FIG. 6. FIG. 12 is a plan view selectively showing only a fifth pattern layer of the components of FIG. 6. FIG. 13 is a plan view selectively showing only a sixth pattern layer of the components of FIG. 6. FIG. 14 is a plan view selectively showing only first to fifth pattern layers of the components of FIG. 6. FIG. 15 is a plan view selectively showing only fifth and sixth pattern layers of the components of FIG. 6. FIG. 16 is a plan view selectively showing only sixth and seventh pattern layers of the components of FIG. 6.

Meanwhile, as shown in FIG. 6, contact holes may be classified into a first type contact hole CTa, a second type contact hole CTb, and a third type contact hole CTc. The first type contact hole CTa may be a contact hole for connecting a fifth pattern layer to a pattern layer (e.g., at least one of second to fourth pattern layers) disposed therebelow. The second type contact hole CTb may be a contact hole for connecting a sixth pattern layer to a pattern layer (e.g., fifth pattern layer) disposed therebelow. The third type contact hole CTc may be a contact hole for connecting a seventh pattern layer to a pattern layer (e.g., sixth pattern layer) disposed therebelow.

A first pattern layer may be disposed on the substrate SUB along the third direction DR3. The first pattern layer may include an active layer ACT as in the example shown in FIGS. 6 and 7.

The active layer ACT may provide channel regions CH1 to CH10, first electrodes E11, E211, E221, E31, E411, E421, E511, E521, E61, E71, E81, E91, and E101, and second electrodes E12, E212, E222, E32, E412, E422, E512, E522, E62, E72, E82, E92, and E102 of the first to tenth transistors T1 to T10. Here, the first electrode of each of the first to tenth transistors T1 to T10 may be one of the source electrode and the drain electrode, and the second electrode of each of the first to tenth transistors T1 to T10 may be the other one of the source electrode and the drain electrode.

The active layer ACT may be a semiconductor layer made of low temperature polycrystalline silicon (LTPS).

The second pattern layer may be disposed on the first pattern layer along the third direction DR3. An insulating layer may be disposed between the first pattern layer and the second pattern layer. As in the example shown in FIGS. 6 and 7, the second pattern layer may include a first gate electrode GE1, a second gate electrode GE2, a third gate electrode GE3, a fourth gate electrode GE4, a fifth gate electrode GE5, a sixth gate electrode GE6, a seventh gate electrode GE7, an eighth gate electrode GE8, a ninth gate electrode GE9, and a tenth gate electrode GE10.

The first to tenth gate electrodes GE1 to GE10 may overlap respective active layers ACT, respectively. The channel regions CH1 to CH10 of the first to tenth transistors T1 to T10 may be formed in overlapping regions between the active layer ACT and the first to tenth gate electrodes GE1 to GE10, respectively.

The first transistor T1 may include the first gate electrode GE1, the first electrode E11, the second electrode E12, and a first channel region CH1.

The second transistor T2 may be formed as a dual gate transistor including a second-first transistor T2-1 and a second-second transistor T2-2. The second-first transistor T2-1 may include a second-first gate electrode GE2-1, the first electrode E211, the second electrode E212, and a second-first channel region CH2-1. The second-second transistor T2-2 may include a second-second gate electrode GE2-2, the first electrode E221, the second electrode E222, and a second-second channel region CH2-2. Here, the second-first gate electrode GE2-1 and the second-second gate electrode GE2-2 may be integrally formed.

The third transistor T3 may include the third gate electrode GE3, the first electrode E31, the second electrode E32, and a third channel region CH3.

The fourth transistor T4 may be formed as a dual gate transistor including a fourth-first transistor T4-1 and a fourth-second transistor T4-2. The fourth-first transistor T4-1 may include a fourth-first gate electrode GE4-1, the first electrode E411, the second electrode E412, and a fourth-first channel region CH4-1. The fourth-second transistor T4-2 may include a fourth-second gate electrode GE4-2, the first electrode E421, the second electrode E422, and a fourth-second channel region CH4-2. Here, the fourth-first gate electrode GE4-1 and the fourth-second gate electrode GE4-2 may be integrally formed.

The fifth transistor T5 may be formed as a dual gate transistor including a fifth-first transistor T5-1 and a fifth-second transistor T5-2. The fifth-first transistor T5-1 may include a fifth-first gate electrode GE5-1, the first electrode E511, the second electrode E512, and a fifth-first channel region CH5-1. The fifth-second transistor T5-2 may include a fifth-second gate electrode GE5-2, the first electrode E521, the second electrode E522, and a fifth-second channel region CH5-2.

The sixth transistor T6 may include the sixth gate electrode GE6, the first electrode E61, the second electrode E62, and a sixth channel region CH6.

The seventh transistor T7 may include the seventh gate electrode GE7, the first electrode E71, the second electrode E72, and a seventh channel region CH7.

The eighth transistor T8 may include the eighth gate electrode GE8, the first electrode E81, the second electrode E82, and an eighth channel region CH8. Here, the eighth gate electrode GE8 and the sixth gate electrode GE6 may be integrally formed.

The ninth transistor T9 may include the ninth gate electrode GE9, the first electrode E91, the second electrode E92, and a ninth channel region CH9. Here, the ninth gate electrode GE9 and the seventh gate electrode GE7 may be integrally formed.

The tenth transistor T10 may include the tenth gate electrode GE10, the first electrode E101, the second electrode E102, and a tenth channel region CH10. Here, as shown in FIG. 14, the tenth gate electrode GE10, the fifth-first gate electrode GE5-1, and the third gate electrode GE3 may be integrally formed.

The third pattern layer may be disposed on the second pattern layer along the third direction DR3. An insulating layer may be disposed between the second pattern layer and the third pattern layer. As in the example shown in FIGS. 6, 8, and 9, the third pattern layer may include a parasitic capacitor electrode PCPE, the first initialization voltage line VIL1, and a lower capacitor electrode CPEa.

The parasitic capacitor electrode PCPE may overlap the active layer ACT, as in the example shown in FIGS. 6 and 9. For example, the parasitic capacitor electrode PCPE may overlap the active layer ACT corresponding to a connection portion between the second-first transistor T2-1 and the second-second transistor T2-2. Here, the second-first transistor T2-1 and the second-second transistor T2-2 are sub-transistors of the second transistor T2 which is a dual gate transistor. In addition, the parasitic capacitor electrode PCPE may overlap the active layer ACT corresponding to a connection portion between the fourth-first transistor T4-1 and the fourth-second transistor T4-2. Here, the fourth-first transistor T4-1 and the fourth-second transistor T4-2 are sub-transistors of the fourth transistor T4 which is a dual gate transistor.

The first initialization line VIL1 may overlap the active layer ACT, as shown in FIGS. 6, 8, and 9. For example, the first initialization line VIL1 may overlap the active layer ACT corresponding to a connection portion between the fifth-first transistor T5-1 and the fifth-second transistor T2-2. Here, the fifth-first transistor T5-1 and the fifth-second transistor T5-2 are sub-transistors of the fifth transistor T5 which is a dual gate transistor. Further, the first initialization line VIL1 may overlap the active layer ACT corresponding to a connection portion between the fourth-first transistor T4-1 and the third transistor T3. Furthermore, the first initialization line VIL1 may overlap the first electrode E31 of the third transistor T3. A parasitic capacitor may be formed in an overlapping region between the first initialization line VIL1 and the active layer ACT. The first initialization line VIL1 may transmit a first initialization voltage.

The lower capacitor electrode CPEa may be disposed to overlap the first gate electrode GE1, as shown in FIGS. 6 and 9. The first capacitor Cst may be formed in a region where the lower capacitor electrode CPEa and the first gate electrode GE1 overlap. For example, the lower capacitor electrode CPEa and the first gate electrode GE1 may correspond to the first electrode and the second electrode of the first capacitor Cst, respectively. In addition, the lower capacitor electrode CPEa may have a hole 40 passing therethrough in the third direction. The first gate electrode GE1 may be connected to the second electrode E32 of the third transistor T3 through the hole 40 of the first capacitor Cst, a second hole 52 of an upper capacitor electrode CPEb, and a gate connection electrode GCE to be described later. Further, the lower capacitor electrode CPEa may be connected to the second electrode E222 of the second-second transistor T2-2 and the first electrode E521 of the fifth-second transistor T5-2 through a first hole 51 of the upper capacitor electrode CPEb and a capacitor connection electrode CCE to be described later. Further, the area of the lower capacitor electrode CPEa may be larger than the area of the first gate electrode GE1. In this case, the area of the lower capacitor electrode CPEa may mean, for example, an area that includes the area (or size) of the hole 40.

The fourth pattern layer may be disposed on the third pattern layer along the third direction DR3. An insulating layer may be disposed between the third pattern layer and the fourth pattern layer. As in the example shown in FIGS. 6, 10, and 11, the fourth pattern layer may include the upper capacitor electrode CPEb and a repair line RPL.

As shown in FIGS. 6 and 11, the upper capacitor electrode CPEb may be disposed to overlap the lower capacitor electrode CPEa and the first gate electrode GE1.

The second capacitor Chold may be formed in a region where the upper capacitor electrode CPEb and the lower capacitor electrode CPEa overlap. For example, the lower capacitor electrode CPEa and the upper capacitor electrode CPEb may correspond to the first electrode and the second electrode of the second capacitor Chold, respectively. Further, the upper capacitor electrode CPEb may have a larger number of holes than the lower capacitor electrode CPEa. For example, the upper capacitor electrode CPEb may have the first hole 51 and the second hole 52 passing therethrough in the third direction. The first gate electrode GE1 may be connected to the second electrode E32 of the third transistor T3 through the hole 40 of the first capacitor Cst, the second hole 52 of the upper capacitor electrode CPEb, and the gate connection electrode GCE. Further, the upper capacitor electrode CPEb may be connected to the driving voltage line VDL, the second electrode E512 of the fifth-first transistor T5-1, the second electrode E102 of the tenth transistor T10, and the first electrode E81 of the eighth transistor T8 through a driving connection electrode VCE. Further, the area of the upper capacitor electrode CPEb may be larger than the area of the lower capacitor electrode CPEa. In this case, the area of the lower capacitor electrode CPEa may mean an area that includes the area (or size) of the hole 40, and the area of the upper capacitor electrode CPEb may mean an area that includes the areas (or sizes) of the first and second holes 51 and 52.

The repair line RPL may, as shown in FIG. 6, overlap an upper pixel connection electrode PCEb and the end of an extension EX of a lower pixel connection electrode PCEa, which will be described later. For example, the repair line RPL may include a repair short portion RSP that is a portion of the repair line RPL protrudes in the second direction DR2 and overlaps a connection portion between the lower pixel connection electrode PCEa and a pixel electrode PE. The repair line RPL may be used to repair a defective pixel, for example. The repair short portion RSP of the repair line RPL is a portion to which laser and the like is irradiated during a repair process of a defective pixel (e.g., an unlit pixel), and the pixel connection electrodes PCEa and PCEb of the defective pixel and the repair line RPL may be connected by the laser irradiation. Meanwhile, in the repair process, before or after the above laser irradiation, for example, a step of separating a connection between one side of the lower pixel connection electrode PCEa of the defective pixel and the corresponding pixel circuit PC may be first performed. For example, a part of the extension EX of the lower pixel connection electrode PCEa may be cut by a laser before or after the laser irradiation. Accordingly, the end of the lower pixel connection electrode PCEa connected to the upper pixel connection electrode PCEb may be disconnected from the fourth node N4 (e.g., a connection portion between the sixth transistor T6 and the seventh transistor T7). After the repair process, the pixel electrode PE of the defective pixel may be applied with a driving voltage through the repair line RPL instead of the pixel circuit PC. The repair line RPL may be connected to a separate dummy pixel, so that the dummy pixel may apply the aforementioned driving voltage to the repair line RPL.

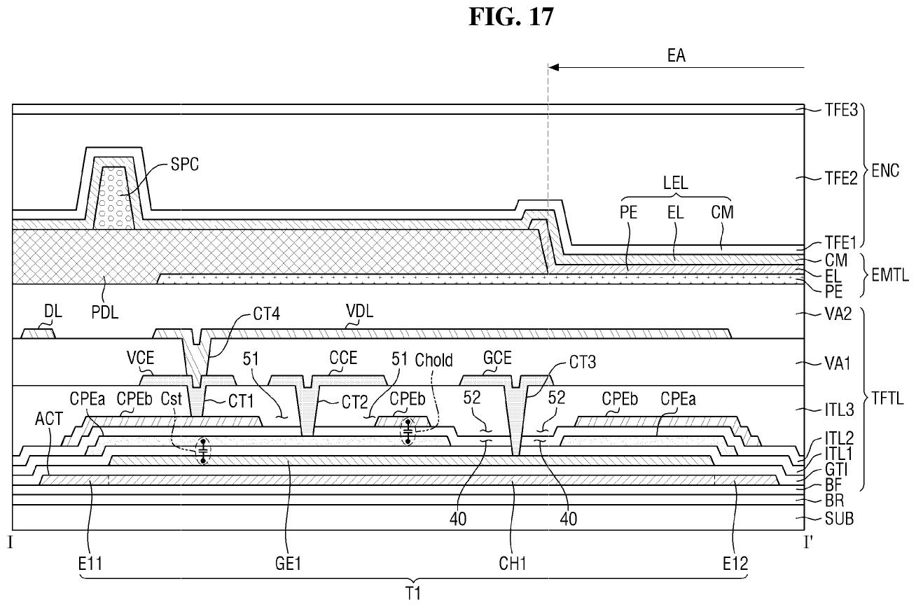

According to the present disclosure, the second electrode (e.g., upper capacitor electrode CPEb) of the second capacitor and the repair line RPL may be formed by the fourth pattern layer. In other words, according to the present disclosure, the upper capacitor electrode CPEb and the repair line RPL may be formed together in a pattern layer (e.g., fourth pattern layer) other than the second pattern layer and the third pattern layer for forming the first capacitor Cst. In this case, since the repair line RPL which is included in the fourth pattern layer is disposed on a different layer from the sixth and eighth gate electrodes GE6 and GE8 which is included in the third pattern layer, as shown in FIG. 11, a minimum distance d1 between the repair line RLP, for example, a repair short portion RSP of the repair line RPL, and the sixth and eighth gate electrodes GE6 and GE8 in the second direction in a plan view may be further reduced. Similarly, since the repair line RPL which is included in the fourth pattern layer is disposed on a different layer from the seventh and ninth gate electrodes GE7 and GE9 which is included in the third pattern layer, as shown in FIG. 11, a minimum distance d2 between the repair line RPL and the seventh and ninth gate electrodes GE7 and GE9 in the second direction in a plan view may be further reduced. In addition, the thickness (e.g., 2500 Å) of the insulating layer (e.g., a first interlayer insulating layer ITL1 and a gate insulating layer GTI of FIG. 17) disposed between the fourth pattern layer (e.g., repair line RPL) and the third pattern layer which includes sixth, seventh, eighth, and ninth gate electrodes GE6, GE7, GE8, and GE9) is thick, so that the minimum distances between the gate electrodes and the repair line (e.g., d1 and d2) may be further reduced without affected by the laser during the repair process. As a result, the pixel size may be reduced, which may increase the resolution.

The fifth pattern layer may be disposed on the fourth pattern layer along the third direction DR3. An insulating layer may be disposed between the fourth pattern layer and the fifth pattern layer. As in the example shown in FIGS. 6, 12, and 14, the fifth pattern layer may include the third gate line GIL, the first gate line GWL, a data connection electrode DCE, an active connection electrode ACE, the second gate line GCL, the driving connection electrode VCE, the capacitor connection electrode CCE, the gate connection electrode GCE, the emission control line EML, the lower pixel connection electrode PCEa, the second initialization voltage line VIL2, and the bias voltage line VBL.

The third gate line GIL may, as shown in FIG. 14, be connected to the fourth-first gate electrode GE4-1 and the fourth-second gate electrode GE4-2 through the first type contact hole of the insulating layer.

The first gate line GWL may, as shown in FIG. 14, be connected to the second-first gate electrode GE2-1 and the second-second gate electrode GE2-2 through the first type contact hole of the insulating layer.

The data connection electrode DCE may, as shown in FIG. 14, be connected to the second electrode E212 (e.g., second electrode E212 of the second-first transistor T2-1) of the active layer ACT through the first type contact hole of the insulating layer.

The active connection electrode ACE may, as shown in FIG. 14, be connected to the second electrode E422 (e.g., second electrode E422 of the fourth-second transistor T4-2) of the active layer ACT and the first electrode E31 (e.g., first electrode E31 of the third transistor T3) of the active layer ACT through the first type contact hole of the insulating layer.

The second gate line GCL may, as shown in FIG. 14, be connected to the tenth gate electrode GE10, the fifth-first gate electrode GE5-1, and the third gate electrode GE3 through the first type contact hole of the insulating layer.

The driving connection electrode VCE may, as shown in FIG. 14, be connected to the second electrode E212 (e.g., second electrode E212 of the second-first transistor T2-1) of the active layer ACT, the upper capacitor electrode CPEb, and the second electrode E82 (e.g., second electrode E82 of the eighth transistor T8) of the active layer ACT through the first type contact hole of the insulating layer.

The capacitor connection electrode CCE may, as shown in FIG. 14, be connected to the second electrode E222 (e.g., second electrode E222 of the second-second transistor T2-2) of the active layer ACT through the first type contact hole of the insulating layer. Further, the capacitor connection electrode CCE may be connected to the lower capacitor electrode CPEa through the first type contact hole of the insulating layer and the first hole 51 of the upper capacitor electrode CPEb.

The gate connection electrode GCE may, as shown in FIG. 14, be connected to the first electrode E31 (e.g., first electrode E31 of the third transistor T3) of the active layer ACT through the first type contact hole of the insulating layer. Further, the gate connection electrode GCE may be connected to the first gate electrode GE1 through the first type contact hole of the insulating layer, the second hole 52 of the upper capacitor electrode CPEb, and the hole 40 of the lower capacitor electrode CPEa.

The emission control line EML may, as shown in FIG. 14, be connected to the sixth gate electrode GE6 and the eighth gate electrode GE8 through the first type contact hole of the insulating layer.

The lower pixel connection electrode PCEa may, as shown in FIG. 14, be connected to the second electrode E62 (e.g., second electrode E62 of the sixth transistor T6) of the active layer ACT through the first type contact hole of the insulating layer.

The second initialization voltage line VIL2 may include a second-first initialization voltage line VIL2-1 and a second-second initialization voltage line VIL2-2 that are separated from each other. The second-first initialization voltage line VIL2-1 and the second-second initialization voltage line VIL2-2 may transmit initialization voltages of different magnitudes.

The second-first initialization voltage line VIL2-1 may be connected to any one of three pixels that display different colors. For example, the second-first initialization voltage line VIL2-1 may be connected to the seventh transistor T7 of a green pixel that provides light corresponding to a green wavelength. For example, the second-first initialization voltage line VIL2-1 may be connected to the second electrode E72 (e.g., second electrode E72 of the seventh transistor T7) of the active layer ACT disposed in a red pixel through the first type contact hole of the insulating layer.

The second-second initialization voltage line VIL2-2 may be connected to the remaining two pixels, which have different colors, of the aforementioned three pixels. For example, the second-second initialization voltage line VIL2-2 may be connected to the seventh transistor T7 of a red pixel that provides light corresponding to a red wavelength, and the seventh transistor T7 of a blue pixel that provides light corresponding to a blue wavelength. For example, the second-second initialization voltage line VIL2-2 may be connected to the second electrode E72 (e.g., second electrode E72 of the seventh transistor T7) of the active layer ACT disposed in a red pixel through the first type contact hole of the insulating layer. In addition, the second-second initialization voltage line VIL2-2 may be connected to the second electrode E72 (e.g., second electrode E72 of the seventh transistor T7) of the active layer ACT disposed in a blue pixel through the first type contact hole of the insulating layer.

The bias voltage line VBL may transmit a bias voltage VB. The bias voltage line VBL may, as shown in FIG. 14, be connected to the second electrode E92 (e.g., second electrode E92 of the ninth transistor T9) of the active layer ACT and the parasitic capacitor electrode PCPE through the first type contact hole of the insulating layer.

The sixth pattern layer may be disposed on the fifth pattern layer along the third direction DR3. An insulating layer may be disposed between the fifth pattern layer and the sixth pattern layer. As in the example shown in FIGS. 6, 13, and 15, the sixth pattern layer may include the data line DL, the driving voltage line VDL, and the upper pixel connection electrode PCEb.

The data line DL may, as shown in FIG. 15, be connected to the data connection electrode DCE through the second type contact hole CTb of the insulating layer.

The driving voltage line VDL may, as shown in FIG. 15, be connected to the driving connection electrode VCE through the second type contact hole CTb of the insulating layer.

The upper pixel connection electrode PCEb may, as shown in FIG. 15, be connected to the lower pixel connection electrode PCEa through the second type contact hole of the insulating layer.

The seventh pattern layer may be disposed on the sixth pattern layer along the third direction DR3. An insulating layer may be disposed between the sixth pattern layer and the seventh pattern layer. As in the example shown in FIGS. 6 and 16, the seventh pattern layer may include the pixel electrode PE.

A part of the pixel electrode PE may be exposed by a bank which will be described later. For example, the bank may have an opening (hereinafter, emission area) through which a part of the pixel electrode PE is exposed. A light emitting layer may be disposed on the pixel electrode PE corresponding to the emission area.

The pixel electrode PE may be connected to the upper pixel connection electrode PCEb through the third type contact hole of the insulating layer.

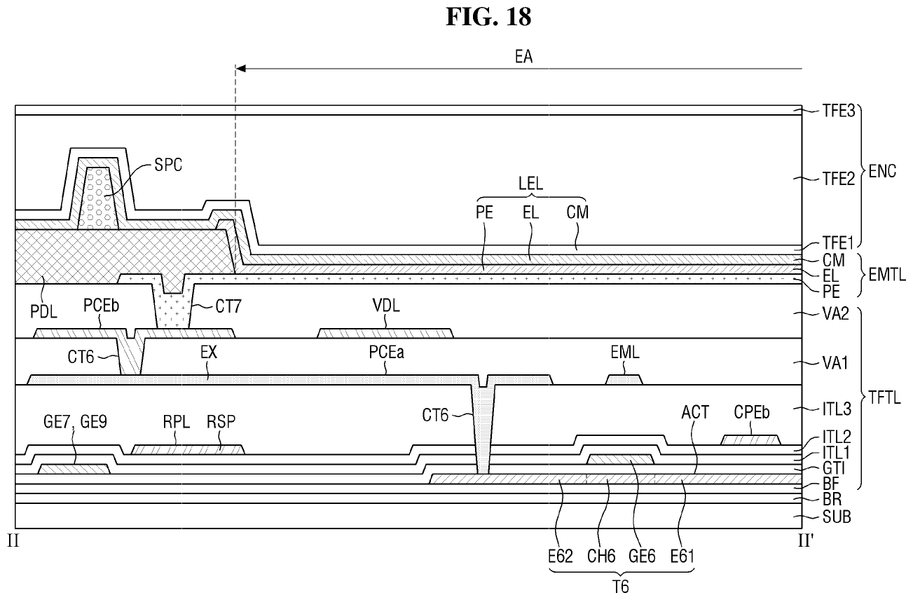

FIG. 17 is a cross-sectional view taken along line I-I′ of FIG. 6, and FIG. 18 is a cross-sectional view taken along line II-II′ of FIG. 6.

As illustrated in FIGS. 17 and 18, the display device 10 may include the substrate SUB, a barrier layer BR, a thin film transistor layer TFTL, a light emitting element layer EMTL, and an encapsulation layer ENC. The barrier layer BR, the thin film transistor layer TFTL, the light emitting element layer EMTL, and the encapsulation layer ENC may be sequentially disposed on the substrate SUB along the third direction DR3.

The substrate SUB may be a rigid substrate or a flexible substrate which can be bent, folded or rolled. The substrate SUB may be formed of an insulating material such as glass, quartz, or a polymer resin. Examples of a polymer material may include polyethersulphone (PES), polyacrylate (PA), polyarylate (PAR), polyetherimide (PEI), polyethylene naphthalate (PEN), polyethylene terephthalate (PET), polyphenylene sulfide (PPS), polyallylate, polyimide (PI), polycarbonate (PC), cellulose triacetate (TAC), cellulose acetate propionate (CAP), or a combination thereof. Alternatively, the substrate SUB may include a metal material.

As illustrated in FIGS. 17 and 18, the barrier layer BR may be disposed on the substrate SUB. The barrier layer BR may be disposed on the entire surface of the substrate SUB. The barrier layer BR may be a layer for protecting the transistors T1 to T8 of the thin film transistor layer TFTL and a light emitting layer EL of the light emitting element layer EMTL from moisture permeating through the substrate SUB which is susceptible to moisture permeation.

The barrier layer BR may be formed as a plurality of inorganic layers that are alternately stacked. For example, the barrier layer BR may be formed of multiple layers in which one or more inorganic layers of a silicon nitride layer, a silicon oxynitride layer, a silicon oxide layer, a titanium oxide layer and an aluminum oxide layer are alternately stacked.

As illustrated in FIGS. 17 and 18, a buffer layer BF may be disposed on the barrier layer BR. The buffer layer BF may be disposed on the entire surface of the substrate SUB including the barrier layer BR. The buffer layer BF may be a layer for protecting the transistors T1 to T8 of the thin film transistor layer TFTL and a light emitting layer EL of the light emitting element layer EMTL from moisture permeating through the substrate SUB which is susceptible to moisture permeation.

The buffer layer BF may be formed of a plurality of inorganic layers that are alternately stacked. For example, the buffer layer BF may be formed of multiple layers in which one or more inorganic layers of a silicon nitride layer, a silicon oxynitride layer, a silicon oxide layer, a titanium oxide layer and an aluminum oxide layer are alternately stacked.

The first pattern layer may be disposed on the buffer layer BF. For example, the active layer ACT may be disposed on the barrier layer BR. As shown in FIGS. 17 and 18, the active layer ACT may include the first electrode E11 of the first transistor T1, the second electrode E12 of the first transistor T1, the first channel region CH1 of the first transistor T1, the first electrode E61 of the sixth transistor T6, the second electrode E62 of the sixth transistor T6, and the sixth channel region CH6 of the sixth transistor T6.

The active layer ACT may be an active layer made of low temperature polycrystalline silicon (LTPS).

The gate insulating layer GTI may be disposed on the first pattern layer. For example, as shown in FIGS. 17 and 18, the gate insulating layer GTI may be disposed on the active layer ACT. In this case, the gate insulating layer GTI may be disposed on the entire surface of the substrate SUB including the first active layer ACT1.

The gate insulating layer GTI may include at least one of tetraethylorthosilicate (TEOS), silicon nitride (SiNx), or silicon oxide (SiO₂). For example, the gate insulating layer GTI may have a double layer structure in which a silicon nitride layer having a thickness of 40 nm and a tetraethylorthosilicate layer having a thickness of 80 nm are sequentially stacked.

The second pattern layer may be disposed on the gate insulating layer GTI. For example, the first gate electrode GE1, the second gate electrode GE2, the third gate electrode GE3, the fourth gate electrode GE4, the fifth gate electrode GE5, the sixth gate electrode GE6, the seventh gate electrode GE7, the eighth gate electrode GE8, the ninth gate electrode GE9, and the tenth gate electrode GE10 may be disposed on the gate insulating layer GTI.

FIGS. 17 and 18 illustrate an example in which the first gate electrode GE1, the sixth gate electrode GE6, the seventh gate electrode GE7, and the ninth gate electrode GE9 are disposed on the gate insulating layer GTI. The first gate electrode GE1 may be disposed on the gate insulating layer GTI to overlap the first channel region CH1 of the active layer ACT. The sixth gate electrode GE6 may be disposed on the gate insulating layer GTI to overlap the sixth channel region CH6 of the active layer ACT.

The second pattern layer may include at least one of molybdenum (Mo), copper (Cu), aluminum, or titanium (Ti), and may be formed of a single layer or multiple layers. For example, the first gate electrode GE1 may be formed of a triple layer including a titanium layer, an aluminum layer, and a titanium layer disposed sequentially on the gate insulating layer GTI along the third direction DR3.

The first interlayer insulating layer ITL1 may be disposed on the second pattern layer. For example, as shown in FIGS. 17 and 18, the first interlayer insulating layer ITL1 may be disposed on the first gate electrode GE1, the sixth gate electrode GE6, the seventh gate electrode GE7, and the ninth gate electrode GE9. In this case, the first interlayer insulating layer ITL1 may be disposed on the entire surface of the substrate SUB including the first gate electrode GE1, the sixth gate electrode GE6, the seventh gate electrode GE7, and the ninth gate electrode GE9.

The first interlayer insulating layer ITL1 may include an inorganic layer, for example, a silicon nitride layer, a silicon oxynitride layer, a silicon oxide layer, a titanium oxide layer, or an aluminum oxide layer. Meanwhile, the first interlayer insulating layer ITL1 may include a plurality of inorganic layers.

The third pattern layer may be disposed on the first interlayer insulating layer ITL1. For example, the parasitic capacitor electrode PCPE, the first initialization voltage line VIL1, and the lower capacitor electrode CPEa may be disposed on the first interlayer insulating layer ITL1. FIG. 17 illustrates an example in which the lower capacitor electrode CPEa is disposed on the first interlayer insulating layer ITL1. The lower capacitor electrode CPEa may be disposed on the first interlayer insulating layer ITL1 to overlap the first gate electrode GE1. The first capacitor Cst may be formed between the lower capacitor electrode CPEa and the first gate electrode GE1.

The third pattern layer may have the same material and structure as the second pattern layer described above.

A second interlayer insulating layer ITL2 may be disposed on the third pattern layer. For example, as shown in FIGS. 17 and 18, the second interlayer insulating layer ITL2 may be disposed on the lower capacitor electrode CPEa. In this case, the second interlayer insulating layer ITL2 may be disposed on the entire surface of the substrate SUB including the lower capacitor electrode CPEa.

The second interlayer insulating layer ITL2 may have the same material and structure as the first interlayer insulating layer described above.

The fourth pattern layer may be disposed on the second interlayer insulating layer ITL2. For example, the upper capacitor electrode CPEb and the repair line RPL may be disposed on the second interlayer insulating layer ITL2. As shown in FIG. 17, the upper capacitor electrode CPEb may be disposed on the second interlayer insulating layer ITL2 to overlap the lower capacitor electrode CPEa. The second capacitor Chold may be formed between the upper capacitor electrode CPEb and the lower capacitor electrode CPEa.

A third interlayer insulating layer ITL3 may be disposed on the fourth pattern layer. For example, as shown in FIGS. 17 and 18, the third interlayer insulating layer ITL3 may be disposed on the upper capacitor electrode CPEb and the repair line RPL. The third interlayer insulating layer ITL3 may be disposed on the entire surface of the substrate SUB including the upper capacitor electrode CPEb and the repair line RPL.

The third interlayer insulating layer ITL3 may have the same material and structure as the first interlayer insulating layer ITL1 described above.

The fifth pattern layer may be disposed on the third interlayer insulating layer ITL3. For example, the third gate line GIL, the first gate line GWL, the data connection electrode DCE, the active connection electrode ACE, the second gate line GCL, the driving connection electrode VCE, the capacitor connection electrode CCE, the gate connection electrode GCE, the emission control line EML, the lower pixel connection electrode PCEa, the second initialization voltage line VIL2, and the bias voltage line VBL may be disposed on the third interlayer insulating layer ITL3. FIGS. 17 and 18 illustrate an example in which the driving connection electrode VCE, the capacitor connection electrode CCE, the gate connection electrode GCE, the lower pixel connection electrode PCEa, and the emission control line EML are disposed on the third interlayer insulating layer ITL3.

The driving connection electrode VCE may be connected to the upper capacitor electrode CPEb through a first contact hole CT1 penetrating the third interlayer insulating layer ITL3.

The capacitor connection electrode CCE may be connected to the lower capacitor electrode CPEa through a second contact hole CT2 penetrating the third interlayer insulating layer ITL3, the first hole 51 of the upper capacitor electrode CPEb, and the second interlayer insulating layer ITL2.

The gate connection electrode GCE may be connected to the first gate electrode GE1 through a third contact hole CT3 penetrating the third interlayer insulating layer ITL3, the second hole 52 of the upper capacitor electrode CPEb, the second interlayer insulating layer ITL2, the hole 40 of the lower capacitor electrode CPEa, and the first interlayer insulating layer ITL1.

The lower pixel connection electrode PCEa may be connected to the second electrode E62 of the sixth transistor T6 through a fifth contact hole CT5 penetrating the third interlayer insulating layer ITL3, the second interlayer insulating layer ITL2, and the first interlayer insulating layer ITL1.

The first contact hole CT1, the second contact hole CT2, the third contact hole CT3, and the fifth contact hole CT5 described above may belong to the first type contact hole CTa.

The fifth pattern layer may have the same material or structure as the second pattern layer described above.

A first planarization layer VA1 may be disposed on the fifth pattern layer. For example, the first planarization layer VA1 may be disposed on the driving connection electrode VCE, the capacitor connection electrode CCE, the gate connection electrode GCE, the lower pixel connection electrode PCEa, and the emission control line EML. The first planarization layer VA1 may be disposed on the entire surface of the substrate SUB including the driving connection electrode VCE, the capacitor connection electrode CCE, the gate connection electrode GCE, the lower pixel connection electrode PCEa, and the emission control line EML.

The first planarization layer VA1 may include an organic layer such as acryl resin, epoxy resin, phenolic resin, polyamide resin, polyimide resin and the like.

The sixth pattern layer may be disposed on the first planarization layer VA1. For example, as shown in FIG. 17, the data line DL, the driving voltage line VDL, and the upper pixel connection electrode PCEb may be disposed on the first planarization layer VA1.

The driving voltage line VDL may be connected to the driving connection electrode VCE through a fourth contact hole CT4 penetrating the first planarization layer VA1.

The upper pixel connection electrode PCEb may be connected to the lower pixel connection electrode PCEa through a sixth contact hole CT6 penetrating the first planarization layer VA1.

The fourth contact hole CT4 and the sixth contact hole CT6 described above may belong to the second type contact hole CTb.

The sixth pattern layer may have the same material or structure as the second pattern layer described above.

A second planarization layer VA2 may be disposed on the sixth pattern layer. For example, the second planarization layer VA2 may be disposed on the data line DL, the driving voltage line VDL, and the upper pixel connection electrode PCEb. The second planarization layer VA2 may be disposed on the entire surface of the substrate SUB including the data line DL, the driving voltage line VDL, and the upper pixel connection electrode PCEb.

The second planarization layer VA2 may have the same material and structure as the first planarization layer VA1 described above.

The seventh pattern layer may be disposed on the second planarization layer VA2. For example, as shown in FIGS. 17 and 18, the light emitting element layer EMTL including the seventh pattern layer may be disposed on the second planarization layer VA2. For example, the pixel electrode PE may be disposed on the second planarization layer VA2, as the seventh pattern layer.

The pixel electrode PE may be connected to the upper pixel connection electrode PCEb through a seventh contact hole CT7 penetrating the second planarization layer VA2.

The aforementioned seventh contact hole CT7 may belong to the third type contact hole CTc.

In addition to the aforementioned seventh pattern layer, the above-described light emitting element layer EMTL may further include a light emitting element LEL and a bank PDL (or pixel defining layer).

The light emitting element LEL may include the pixel electrode PE, the light emitting layer EL, and a common electrode CM. The emission area EA, in which the pixel electrode PE, the light emitting layer EL, and the common electrode CM are sequentially stacked, indicates an area in which holes from the pixel electrode PE and electrons from the common electrode CM are combined with each other in the light emitting layer to emit light. In this case, the pixel electrode PE may be the anode electrode of the light emitting element LEL, and the common electrode CM may be the cathode electrode of the light emitting element LEL.

In a top emission structure that emits light toward the common electrode CM with respect to the light emitting layer EL, the pixel electrode PE may be formed of a single layer of molybdenum (Mo), titanium (Ti), copper (Cu), or aluminum (Al), or may be formed to have a stacked structure (Ti/Al/Ti) of aluminum and titanium, a stacked structure (ITO/AI/ITO) of aluminum and ITO, an APC alloy, or a stacked structure (ITO/APC/ITO) of APC alloy and ITO to increase the reflectivity. The APC alloy is an alloy of silver (Ag), palladium (Pd) and copper (Cu).

The bank PDL (or pixel defining layer) may serve to define the emission areas EA of pixels. To this end, the bank PDL may be disposed to expose a part of the pixel electrode PE on the second planarization layer VA2. The bank PDL may cover the edge of the pixel electrode PE. Meanwhile, the bank PDL may fill a recessed portion disposed on the seventh contact hole CT7 penetrating the second planarization layer VA2. Accordingly, the recessed portion disposed on the seventh contact hole CT7 penetrating the second planarization layer VA2 may be filled by the bank PDL. The bank PDL may be formed of an organic layer such as acryl resin, epoxy resin, phenolic resin, polyamide resin, polyimide resin and the like.

As shown in FIGS. 17 and 18, a spacer SPC may be disposed on the bank PDL. The spacer SPC may serve to support a mask during a process of manufacturing the light emitting layer EL. The spacer SPC may be formed of an organic layer such as acryl resin, epoxy resin, phenolic resin, polyamide resin, polyimide resin and the like. The spacer SPC may have the same material as the bank PDL and may be formed at the same time as the bank PDL by using, for example, a halftone mask.

The light emitting layer EL may be formed on the pixel electrode PE. The light emitting layer EL may include an organic material to emit light in a predetermined color. For example, the light emitting layer EL may include a hole transporting layer, an organic material layer, and an electron transporting layer. The organic material layer may include a host and a dopant. The organic material layer may include a material that emits predetermined light, and may be formed using a phosphorescent material or a fluorescent material.

The aforementioned light emitting element LEL may be provided for each pixel. For example, a first pixel may include a first light emitting element, a second pixel may include a second light emitting element, and a third pixel may include a third light emitting element. The first light emitting element, the second light emitting element, and the third light emitting element may provide lights of different colors. For example, the first light emitting element may emit light of a first color, the second light emitting element may emit light of a second color, and the third light emitting element may emit light of a third color.

For example, the organic material layer of the first light emitting layer of the first emission area emitting the light of the first color may be a phosphorescent material including a host material including carbazole biphenyl (CBP) or mCP (1,3-bis(carbazol-9-yl), and a dopant including at least one selected from the group consisting of PIQIr(acac)(bis(1-phenylisoquinoline)acetylacetonate iridium), PQIr(acac)(bis(1-phenylquinoline)acetylacetonate iridium), PQIr(tris(1-phenylquinoline)iridium)) and PtOEP (octaethylporphyrin platinum). Alternatively, the organic material layer of the first light emitting layer of the first emission area may be a fluorescent material including PBD:Eu(DBM)3(Phen) or Perylene, but the present disclosure is not limited thereto.

The organic material layer of the second light emitting layer of the second emission area emitting the light of the second color may be a phosphorescent material including a host material including CBP or mCP, and a dopant material including Ir(ppy)3(fac tris(2-phenylpyridine) iridium. Alternatively, the organic material layer of the second light emitting layer of the second emission area emitting the light of the second color may be a fluorescent material including tris(8-hydroxyquinolino)aluminum (Alq3), but the present disclosure is not limited thereto.

The organic material layer of the light emitting layer of the third emission area emitting the light of the third color may be a phosphorescent material including a host material including CBP or mCP, and a dopant material including (4,6-F2ppy)2Irpic or L2BD111, but the present disclosure is not limited thereto.

The common electrode CM may be disposed on the first, second, and third light emitting layers (e.g., EL). The common electrode CM may be disposed to cover the first, second, and third light emitting layers. The common electrode CM may be a common layer commonly disposed in the first to third light emitting layers. A capping layer may be formed on the common electrode CM.

In the top emission structure, the common electrode CM may be formed of a transparent conductive material (TCO) such as ITO or IZO capable of transmitting light or a semi-transmissive conductive material such as magnesium (Mg), silver (Ag), or an alloy of magnesium (Mg) and silver (Ag). When the common electrode CM is formed of a semi-transmissive conductive material, the light emission efficiency can be increased due to a micro-cavity effect.

The encapsulation layer ENC may be formed on the light emitting element layer EMTL. The encapsulation layer ENC may include at least one inorganic layer TFE1 and TFE3 to prevent oxygen or moisture from permeating into the light emitting element layer EMTL. In addition, the encapsulation layer ENC may include at least one organic layer to protect the light emitting element layer EMTL from foreign substances such as dust. For example, the encapsulation layer ENC may include a first inorganic encapsulation layer TFE1, an organic encapsulation layer TFE2, and a second inorganic encapsulation layer TFE3.

The first inorganic encapsulation layer TFE1 may be disposed on the common electrode CM, the organic encapsulation layer TFE2 may be disposed on the first inorganic encapsulation layer TFE1, and the second inorganic encapsulation layer TFE3 may be disposed on the organic encapsulation layer TFE2. The first inorganic encapsulation layer TFE1 and the second inorganic encapsulation layer TFE3 may be formed of a multilayer in which one or more inorganic layers of a silicon nitride layer, a silicon oxynitride layer, a silicon oxide layer, a titanium oxide layer and an aluminum oxide layer are alternately stacked. The encapsulation organic layer TFE2 may be an organic layer such as acryl resin, epoxy resin, phenolic resin, polyamide resin, polyimide resin or the like.

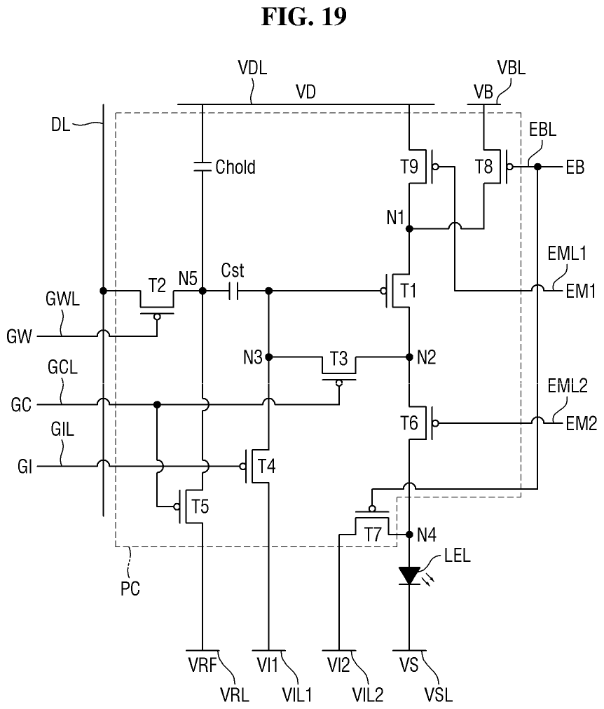

FIG. 19 is a circuit diagram of one pixel of a display device according to one embodiment.

The pixel PX may be connected to the first gate line GWL, the second gate line GCL, the third gate line GIL, the fourth gate line EBL, a first emission control line EML1, a second emission control line EML2, the data line DL, the driving voltage line VDL, the common voltage line VSL, a reference voltage line VRL, the first initialization voltage line VIL1, the second initialization voltage line VIL2, and the bias voltage line VBL.

The pixel (e.g., PX) may include the pixel circuit PC and the light emitting element ED. The pixel circuit PC may include a first transistor T1, a second transistor T2, a third transistor T3, a fourth transistor T4, a fifth transistor T5, a sixth transistor T6, a seventh transistor T7, an eighth transistor T8, a ninth transistor T9, a first capacitor Cst, and a second capacitor Chold.

The first transistor T1 may include a gate electrode, a source electrode, and a drain electrode. The first transistor T1 may control a source-drain current (hereinafter, a driving current) according to the data voltage applied to the gate electrode. The driving current (e.g., Isd) flowing through a channel region of the first transistor T1 may be proportional to the square of a difference between the threshold voltage Vth and the voltage Vsg between the source electrode and the gate electrode of the first transistor T1 (Isd=k×(Vsg−Vth)²). Here, k is a proportional coefficient determined by the structure and physical characteristics of the first transistor T1, Vsg is a source-gate voltage of the first transistor ST1, and Vth is a threshold voltage of the first transistor T1.

The light emitting element ED may emit light by receiving the driving current Isd. The emission amount or the luminance of the light emitting element ED may be proportional to the magnitude of the driving current Isd.

The light emitting element ED may be an organic light emitting diode including a first electrode, a second electrode, and an organic light emitting layer disposed between the first electrode and the second electrode. For another example, the light emitting element ED may be an inorganic light emitting element including a first electrode, a second electrode, and an inorganic semiconductor disposed between the first electrode and the second electrode. For still another example, the light emitting element ED may be a quantum dot light emitting element including a first electrode, a second electrode, and a quantum dot light emitting layer disposed between the first electrode and the second electrode. For still another example, the light emitting element ED may be a micro light emitting diode.

The first electrode of the light emitting element ED may be electrically connected to a fourth node N4. The first electrode of the light emitting element ED may be connected to the drain electrode of the sixth transistor T6 and the source electrode of the seventh transistor T7 through the fourth node N4. The second electrode of the light emitting element ED may be connected to the common voltage line VSL. The second electrode of the light emitting element ED may receive the common voltage VS (e.g., low potential voltage) from the common voltage line VSL.

The second transistor T2 may be turned on by the first gate signal GW of the first gate line GWL to electrically connect the data line DL with a fifth node N5. The drain electrode of the second transistor T2, the first electrode of the first capacitor Cst, the first electrode of the second capacitor Chold, and the source electrode of the fifth transistor T5 may be connected to the fifth node N5. The second transistor T2 may be turned on in response to the first gate signal GW to supply the data voltage to the fifth node N5. The gate electrode of the second transistor T2 may be electrically connected to the first gate line GWL, the source electrode thereof may be electrically connected to the data line DL, and the drain electrode thereof may be electrically connected to the fifth node N5. Meanwhile, the second transistor T2 may be configured as a dual gate transistor. For example, the second transistor T2 may include a second-first transistor and a second-second transistor connected in series between the data line DL and the fifth node N5. The gate electrode of the second-first transistor may be electrically connected to the first gate line GWL, the source electrode thereof may be electrically connected to the data line DL, and the drain electrode thereof may be electrically connected to the source electrode of the second-second transistor. The gate electrode of the second-second transistor may be electrically connected to the first gate line GWL, the source electrode thereof may be electrically connected to the drain electrode of the second-first transistor, and the drain electrode thereof may be electrically connected to the fifth node N5.

The third transistor T3 may be turned on by the second gate signal GC of the second gate line GCL to electrically connect a third node N3 to a second node N2. For example, the gate electrode of the third transistor T3 may be electrically connected to the second gate line GCL, the source electrode thereof may be electrically connected to the third node N3, and the drain electrode thereof may be electrically connected to the second node N2. The source electrode of the third transistor T3, the second electrode of the first capacitor Cst, and the gate electrode of the first transistor T1 may be connected to the third node N3. The drain electrode of the third transistor T3, the drain electrode of the first transistor T1, and the drain electrode of the sixth transistor T6 may be connected to the second node N2. The third transistor T3 may be turned on by the second gate signal GC of the second gate line GCL to electrically connect the second node N2 to the third node N3. Meanwhile, the third transistor T3 may be configured as a dual gate transistor. For example, the third transistor T3 may include a third-first transistor and a third-second transistor connected in series between the third node N3 and the second node N2. The gate electrode of the third-first transistor may be electrically connected to the second gate line GCL, the source electrode thereof may be electrically connected to the third node N3, and the drain electrode thereof may be electrically connected to the source electrode of the third-second transistor. The gate electrode of the third-second transistor may be electrically connected to the second gate line GCL, the source electrode thereof may be electrically connected to the drain electrode of the third-first transistor, and the drain electrode thereof may be electrically connected to the second node N2.

The fourth transistor T4 may be turned on by a third gate signal GI of the third gate line GIL to electrically connect the third node N3 to the first initialization voltage line VIL1. The fourth transistor T4 may be connected in series between the third node N3 and the first initialization voltage line VIL1. For example, the gate electrode of the fourth transistor T4 may be electrically connected to the third gate line GIL, the source electrode thereof may be electrically connected to the third node N3, and the drain electrode thereof may be electrically connected to the first initialization voltage line VIL1. Meanwhile, the fourth transistor T4 may be configured as a dual gate transistor. For example, the fourth transistor T4 may include a fourth-first transistor and a fourth-second transistor connected in series.

The gate electrode of the fourth-first transistor may be electrically connected to the third gate line GIL, the drain electrode thereof may be electrically connected to the first initialization voltage line VIL1, and the source electrode thereof may be connected to the drain electrode of the fourth-second transistor. The gate electrode of the fourth-second transistor may be electrically connected to the third gate line GIL, the drain electrode thereof may be connected to the source electrode of the fourth-first transistor, and the source electrode thereof may be electrically connected to the third node N3.

The fifth transistor T5 may be turned on by the second gate signal GC of the second gate line GCL to electrically connect the reference voltage line VRL to the fifth node N5. For example, the gate electrode of the fifth transistor T5 may be electrically connected to the second gate line GCL, the source electrode thereof may be electrically connected to the fifth node N5, and the drain electrode thereof may be electrically connected to the reference voltage line VRL. The fifth transistor T5 may be turned on by the second gate signal GC of the second gate line GCL to electrically connect the reference voltage line VRL to the fifth node N5. Meanwhile, the fifth transistor T5 may be configured as a dual gate transistor. For example, the fifth transistor T5 may include a fifth-first transistor and a fifth-second transistor connected in series. The gate electrode of the fifth-first transistor may be electrically connected to the second gate line GCL, the source electrode thereof may be connected to the fifth node N5, and the drain electrode thereof may be electrically connected to the source electrode of the fifth-second transistor. The gate electrode of the fifth-second transistor may be electrically connected to the second gate line GCL, the source electrode thereof may be connected to the source electrode of the fifth-first transistor, and the drain electrode thereof may be electrically connected to the reference voltage line VRL.

The sixth transistor T6 may be turned on by a second emission control signal EM2 of the second emission control line EML2 to electrically connect the second node N2 to the fourth node N4, which is the first electrode of the light emitting element ED. The gate electrode of the sixth transistor T6 may be electrically connected to the emission control line EML, the source electrode thereof may be electrically connected to the second node N2, and the drain electrode thereof may be electrically connected to the fourth node N4.

The seventh transistor T7 may be turned on by a fourth gate signal EB of the fourth gate line EBL to electrically connect the fourth node N4 that is the first electrode of the light emitting element ED with the second initialization voltage line VIL2. By turning on the seventh transistor T7 in response to the fourth gate signal, the first electrode of the light emitting element ED may be discharged to a second initialization voltage VI2. The gate electrode of the seventh transistor T7 may be electrically connected to the fourth gate line EBL, the source electrode thereof may be electrically connected to the fourth node N4, and the drain electrode thereof may be electrically connected to the second initialization voltage line VIL2. The second initialization voltage line VIL2 may transmit a second initialization voltage VI2 to the fourth nod N4 which is connected to the anode of the light emitting layer LEL.

The eighth transistor T8 may be turned on by the fourth gate signal EB of the fourth gate line EBL to electrically connect the bias voltage line VBL with a first node N1. The eighth transistor T8 may be turned on according to the fourth gate signal EB to supply a bias voltage VB to the first node N1. The eighth transistor T8 may improve hysteresis of the first transistor T1 by supplying the bias voltage VB to the source electrode of the first transistor T1 connected to the first node N1. The gate electrode of the eighth transistor T8 may be electrically connected to the fourth gate line EBL, the source electrode thereof may be electrically connected to the bias voltage line VBL, and the drain electrode thereof may be electrically connected to the first node N1.

The ninth transistor T9 may be turned on by a first emission control signal EM1 of the first emission control line EML1 to electrically connect the driving voltage line VDL with the first node N1. The gate electrode of the ninth transistor T9 may be electrically connected to the first emission control line EML1, the source electrode thereof may be electrically connected to the driving voltage line VDL, and the drain electrode thereof may be electrically connected to the first node N1. The drain electrode of the eighth transistor T8, the source electrode of the first transistor T1, and the drain electrode of the ninth transistor T9 may be connected to the first node N1.

When all of the ninth transistor T9, the first transistor T1, and the sixth transistor T6 are turned on, the driving current may be supplied to the light emitting element ED.

Each of the first to ninth transistors T1 to T9 may include a silicon-based active layer. For example, each of the first to ninth transistors T1 to T9 may be a p-type transistor including an active layer made of low temperature polycrystalline silicon (LTPS). The active layer made of low temperature polycrystalline silicon may have high electron mobility and excellent turn-on characteristics. Accordingly, in the display device 10, since the transistors having excellent turn-on characteristics are included, it is possible to stably and efficiently drive the plurality of pixels PX. Each of the first to ninth transistors T1 to T9 may output a current flowing into the source electrode to the drain electrode in response to a gate low voltage applied to the gate electrode of the corresponding transistor.

Alternatively, some of the first to ninth transistors T1 to T9 described above may be p-type transistors including an active layer made of low temperature polycrystalline silicon (LTPS) described above, while the others of the first to ninth transistors T1 to T9 may be n-type transistors including an oxide-based active layer. The transistor including the oxide-based active layer may have a coplanar structure in which a gate electrode is disposed thereon. The transistor including the oxide-based active layer may output a current flowing from the drain electrode to the source electrode in response to a gate high voltage applied to the gate electrode.

The first capacitor Cst may be electrically connected between the fifth node N5 and the third node N3. For example, the first electrode of the first capacitor Cst may be electrically connected to the fifth node N5, and the second electrode of the first capacitor Cst may be electrically connected to the third node N3. The first capacitor Cst may maintain the data voltage supplied from the data line DL through the second transistor T2 for one frame period.

The second capacitor Chold may be electrically connected between the driving voltage line VDL and the fifth node N5. For example, the first electrode of the second capacitor Chold may be electrically connected to the fifth node N5, and the second electrode of the second capacitor Chold may be electrically connected to the driving voltage line VDL. The second capacitor Chold may maintain a potential difference between the driving voltage line VDL and the gate electrode of the first transistor T1.

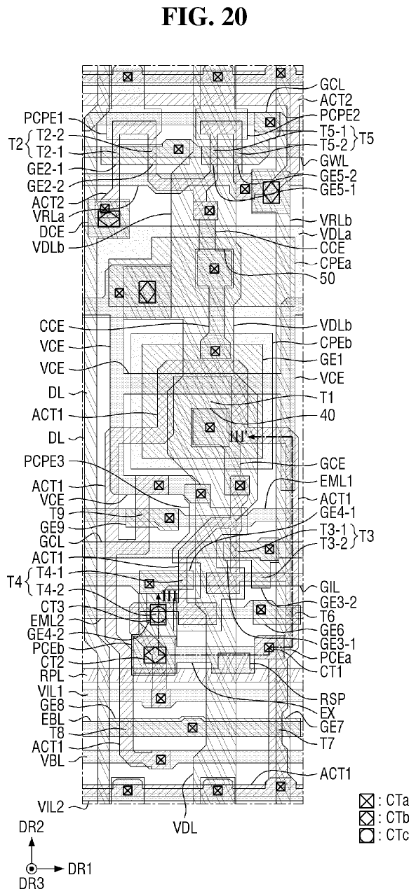

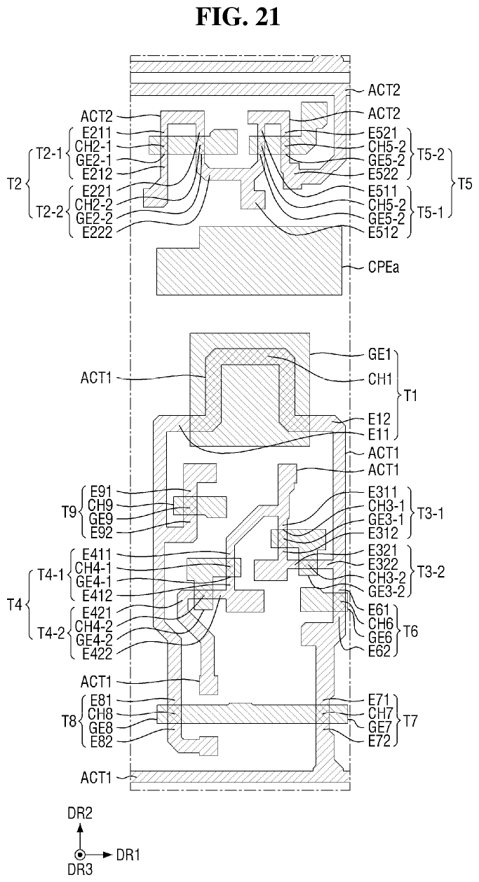

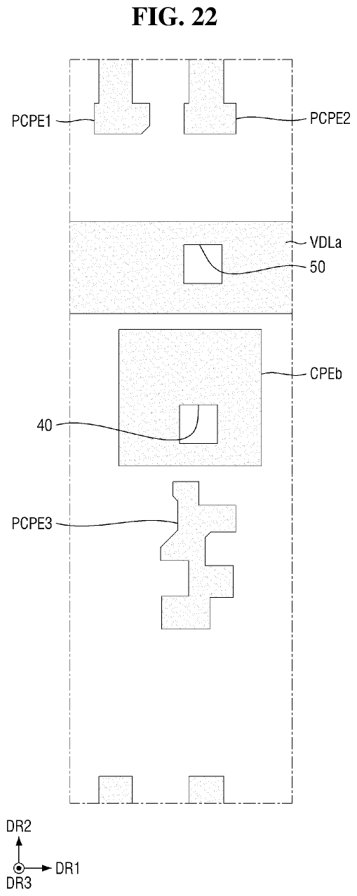

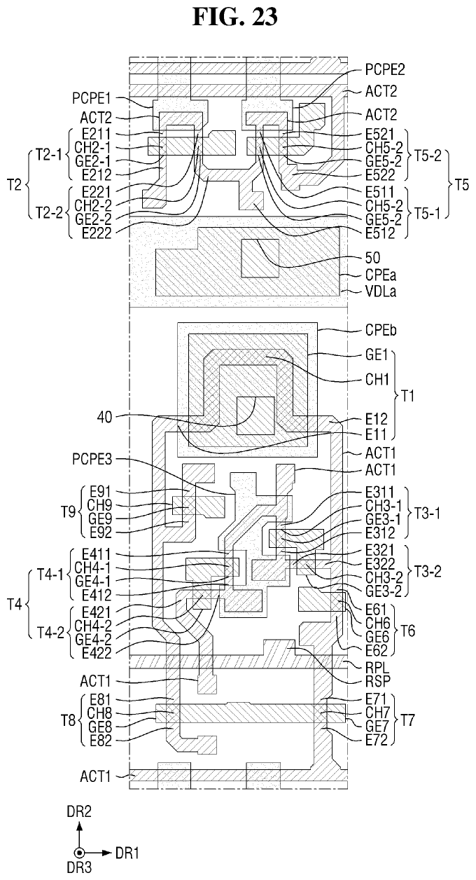

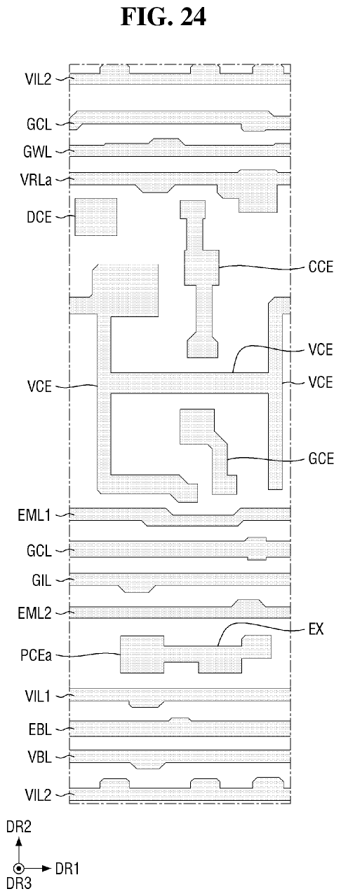

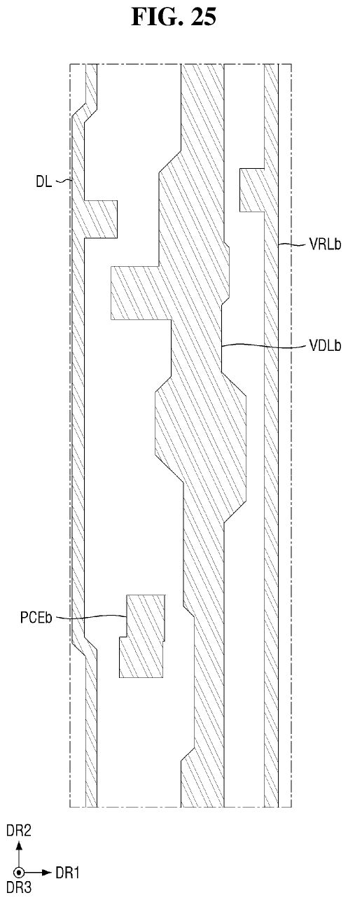

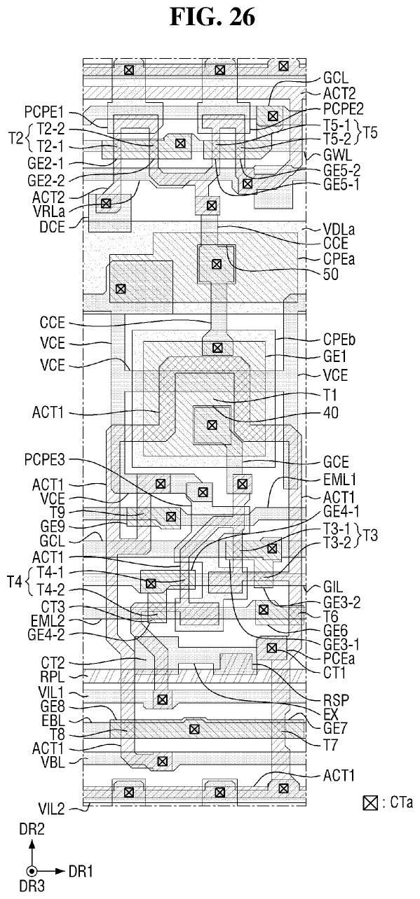

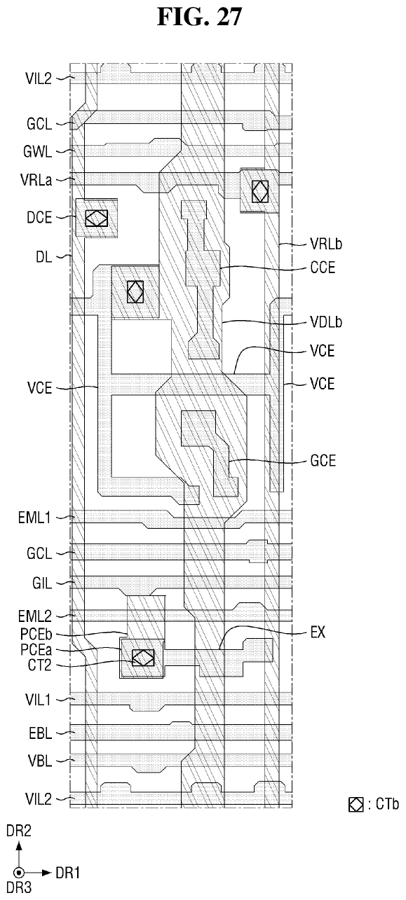

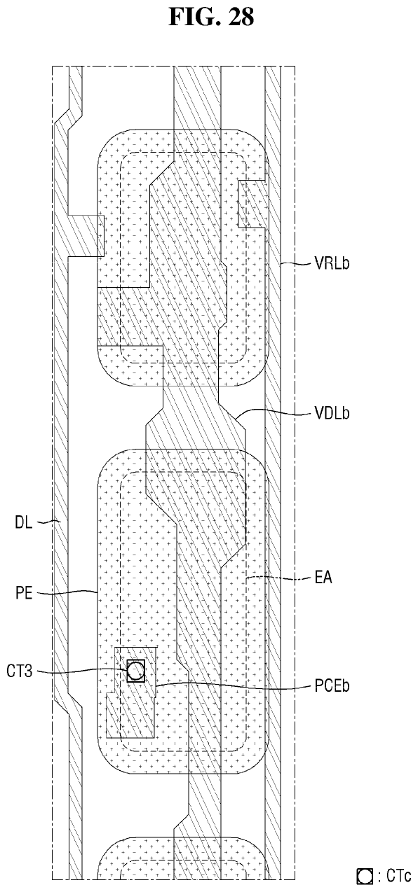

FIG. 20 is a plan view of a unit pixel array according to one embodiment. FIG. 21 is a plan view selectively showing only first and second pattern layers of the components of FIG. 20. FIG. 22 is a plan view selectively showing only a third pattern layer of the components of FIG. 20. FIG. 23 is a plan view selectively showing only first to fourth pattern layers of the components of FIG. 20. FIG. 24 is a plan view selectively showing only a fifth pattern layer of the components of FIG. 20. FIG. 25 is a plan view selectively showing only a sixth pattern layer of the components of FIG. 20. FIG. 26 is a plan view selectively showing only first to fifth pattern layers of the components of FIG. 20. FIG. 27 is a plan view selectively showing only fifth and sixth pattern layers of the components of FIG. 20. FIG. 28 is a plan view selectively showing only sixth and seventh pattern layers of the components of FIG. 20.

Meanwhile, as shown in FIG. 20, contact holes may be classified into the first type contact hole CTa, the second type contact hole CTb, and the third type contact hole CTc. The first type contact hole CTa may be a contact hole for connecting a fifth pattern layer to a pattern layer (e.g., at least one of second to fourth pattern layers) disposed therebelow. The second type contact hole CTb may be a contact hole for connecting a sixth pattern layer to a pattern layer (e.g., fifth pattern layer) disposed therebelow. The third type contact hole CTc may be a contact hole for connecting a seventh pattern layer to a pattern layer (e.g., sixth pattern layer) disposed therebelow.

A first pattern layer may be disposed on the substrate SUB along the third direction DR3. As in the example shown in FIGS. 20 and 21, the first pattern layer may include a first active layer ACT1 and a second active layer ACT2.

The first active layer ACT1 may provide channel regions CH1, CH3, CH4, CH6, CH7, CH8, and CH9, first electrodes E11, E31, E411, E421, E61, E71, E81, and E91, and second electrodes E12, E32, E412, E422, E62, E72, E82, and E92 of the first, third, fourth, sixth, seventh, eighth, and ninth transistors T1, T3, T4, T6, T7, T8, and T9.

The second active layer ACT2 may provide channel regions CH2 and CH5, first electrodes E211, E221, E511, and E521, and second electrodes E212, E222, E512, and E522 of the second and fifth transistors T2 and T5.

Here, the first electrode of each of the first to ninth transistors T1 to T9 may be one of the source electrode and the drain electrode, and the second electrode of each of the first to ninth transistors T1 to T9 may be the other one of the source electrode and the drain electrode.

Each of the first active layer ACT1 and the second active layer ACT2 may be a semiconductor layer made of low temperature polycrystalline silicon (LTPS).

The second pattern layer may be disposed on the first pattern layer along the third direction DR3. An insulating layer may be disposed between the first pattern layer and the second pattern layer. As in the example shown in FIGS. 20 and 21, the second pattern layer may include a first gate electrode GE1, a second-first gate electrode GE2-1, a second-second gate electrode GE2-2, a third-first gate electrode GE3-1, a third-second gate electrode GE3-2, a fourth-first gate electrode GE4-1, a fourth-second gate electrode GE4-2, a fifth-first gate electrode GE5-1, a fifth-second gate electrode GE5-2, a sixth gate electrode GE6, a seventh gate electrode GE7, an eighth gate electrode GE8, a ninth gate electrode GE9, and a lower capacitor electrode CPEa.

The first, third-first, third-second, fourth-first, fourth-second, sixth, seventh, eighth, and ninth gate electrodes GE1, GE3-1, GE3-2, GE4-1, GE4-2, GE6, GE7, GE8, and GE9 may overlap the first active layer ACT1. Channel regions CH1, CH3-1, CH3-2, CH4-1, CH4-2, CH6, CH7, CH8, and CH9 of first, third-first, third-second, fourth-first, fourth-second, sixth, seventh, eighth, and ninth transistors T1, T3-1, T3-2, T4-1, T4-2, T6, T7, T8, and T9 may be formed in overlapping regions between the first active layer ACT1 and the first, third-first, third-second, fourth-first, fourth-second, sixth, seventh, eighth, and ninth gate electrodes GE1, GE3-1, GE3-2, GE4-1, GE4-2, GE6, GE7, GE8, and GE9, respectively.

The second-first, second-second, fifth-first, and fifth-second gate electrodes GE2-1, GE2-2, GE5-1, and GE5-2 may overlap the second active layer ACT2. Channel regions CH2-1, CH2-2, CH5-1, and CH5-2 of second-first, second-second, fifth-first, and fifth-second transistors T2-1, T2-2, T5-1, and T5-2 may be formed in overlapping regions between the second active layer ACT2 and the second-first, second-second, fifth-first, and fifth-second gate electrodes GE2-1, GE2-2, GE5-1, and GE5-2, respectively.

The first transistor T1 may include the first gate electrode GE1, the first electrode E11, the second electrode E12, and a first channel region CH1.

The second transistor T2 may be formed as a dual gate transistor including the second-first transistor T2-1 and the second-second transistor T2-2. The second-first transistor T2-1 may include the second-first gate electrode GE2-1, the first electrode E211, the second electrode E212, and a second-first channel region CH2-1. The second-second transistor T2-2 may include the second-second gate electrode GE2-2, the first electrode E221, the second electrode E222, and a second-second channel region CH2-2. Here, the second-first gate electrode GE2-1 and the second-second gate electrode GE2-2 may be integrally formed.

The third transistor T3 may include a third gate electrode GE3, the first electrode E31, the second electrode E32, and a third channel region CH3. The third transistor T3 may be formed as a dual gate transistor including the third-first transistor T3-1 and the third-second transistor T3-2. The third-first transistor T3-1 may include the third-first gate electrode GE3-1, a first electrode E311, a second electrode E312, and a third-first channel region CH3-1. The third-second transistor T3-2 may include the third-second gate electrode GE3-2, a first electrode E321, a second electrode E322, and a third-second channel region CH3-2. Here, the third-first gate electrode GE3-1 and the third-second gate electrode GE3-2 may be integrally formed.

The fourth transistor T4 may be formed as a dual gate transistor including the fourth-first transistor T4-1 and the fourth-second transistor T4-2. The fourth-first transistor T4-1 may include the fourth-first gate electrode GE4-1, the first electrode E411, the second electrode E412, and a fourth-first channel region CH4-1. The fourth-second transistor T4-2 may include the fourth-second gate electrode GE4-2, the first electrode E421, the second electrode E422, and a fourth-second channel region CH4-2. Here, the fourth-first gate electrode GE4-1 and the fourth-second gate electrode GE4-2 may be integrally formed.

The fifth transistor T5 may be formed as a dual gate transistor including the fifth-first transistor T5-1 and the fifth-second transistor T5-2. The fifth-first transistor T5-1 may include the fifth-first gate electrode GE5-1, the first electrode E511, the second electrode E512, and a fifth-first channel region CH5-1. The fifth-second transistor T5-2 may include the fifth-second gate electrode GE5-2, the first electrode E521, the second electrode E522, and a fifth-second channel region CH5-2.

The sixth transistor T6 may include the sixth gate electrode GE6, the first electrode E61, the second electrode E62, and a sixth channel region CH6.

The seventh transistor T7 may include the seventh gate electrode GE7, the first electrode E71, the second electrode E72, and a seventh channel region CH7.

The eighth transistor T8 may include the eighth gate electrode GE8, the first electrode E81, the second electrode E82, and an eighth channel region CH8. Here, the eighth gate electrode GE8 and the seventh gate electrode GE7 may be integrally formed.

The ninth transistor T9 may include the ninth gate electrode GE9, the first electrode E91, the second electrode E92, and a ninth channel region CH9.

The third pattern layer may be disposed on the second pattern layer along the third direction DR3. An insulating layer may be disposed between the second pattern layer and the third pattern layer. As in the example shown in FIGS. 20, 22, and 23, the third pattern layer may include a first parasitic capacitor electrode PCPE1, a second parasitic capacitor electrode PCPE2, a third parasitic capacitor electrode PCPE3, a lower driving voltage line VDLa, and an upper capacitor electrode CPEb.

The first parasitic capacitor electrode PCPE1 may overlap the active layer ACT, as in the example shown in FIGS. 20 and 23. For example, the first parasitic capacitor electrode PCPE1 may overlap the second active layer ACT2 corresponding to a connection portion between the second-first transistor T2-1 and the second-second transistor T2-2. Here, the second-first transistor T2-1 and the second-second transistor T2-2 are sub-transistors of the second transistor T2 which is a dual gate transistor.

The second parasitic capacitor electrode PCPE2 may overlap the second active layer ACT2 corresponding to a connection portion between the fifth-first transistor T5-1 and the fifth-second transistor T5-2. Here, the fifth-first transistor T5-1 and the fifth-second transistor T5-2 are sub-transistors of the fifth transistor T5, which is a dual gate transistor.

The third parasitic capacitor electrode PCPE3 may overlap the first active layer ACT1 corresponding to a connection portion between the third-first transistor T3-1 and the fourth-first transistor T4-1. Further, the third parasitic capacitor electrode PCPE3 may overlap the first active layer ACT1 corresponding to a connection portion between the third-first transistor T3-1 and the third-second transistor T3-2. Here, the third-first transistor T3-1 and the third-second transistor T3-2 are sub-transistors of the third transistor T3 which is a dual gate transistor. Further, the third parasitic capacitor electrode PCPE3 may overlap the first active layer ACT1 corresponding to a connection portion between the fourth-first transistor T4-1 and the fourth-second transistor T4-2. Here, the fourth-first transistor T4-1 and the fourth-second transistor T4-2 are sub-transistors of the fourth transistor T4 which is a dual gate transistor.

The lower driving voltage line VDLa may overlap the lower capacitor electrode CPEa. The second capacitor Chold may be formed in a region where the lower driving voltage line VDLa and the lower capacitor electrode CPEa overlap. For example, the lower capacitor electrode CPEa and the lower driving voltage line VDLa may correspond to the first electrode and the second electrode of the second capacitor Chold, respectively. Further, the lower driving voltage line VDLa may have a hole 50 passing therethrough in the third direction DR3.

The upper capacitor electrode CPEb may overlap the first gate electrode GE1. The first capacitor Cst may be formed in a region where the upper capacitor electrode CPEb and the first gate electrode GE1 overlap. For example, the first gate electrode GE1 and the upper capacitor electrode CPEb may correspond to the first electrode and the second electrode of the first capacitor Cst, respectively. Further, the upper capacitor electrode CPEb may have a hole 40 passing therethrough in the third direction DR3. Furthermore, the area of the upper capacitor electrode CPEb may be larger than the area of the first gate electrode GE1. In this case, the area of the upper capacitor electrode CPEb may mean, for example, an area that includes the area (or size) of the hole 40.

The fourth pattern layer may be disposed on the third pattern layer along the third direction DR3. An insulating layer may be disposed between the third pattern layer and the fourth pattern layer. As in the example shown in FIGS. 20 and 23, the fourth pattern layer may include a repair line RPL.

As shown in FIG. 20, the repair line RPL may overlap an extension EX of a lower pixel connection electrode PCEa which will be described later. For example, the repair line RPL may include a repair short portion RSP that is a portion of the repair line RPL protruding in the second direction DR2 and overlaps the lower pixel connection electrode PCEa. The repair line RPL may be used to repair a defective pixel, for example. For a description of the repair line RPL, reference may be made to the description of the repair line RPL of FIG. 6 above.

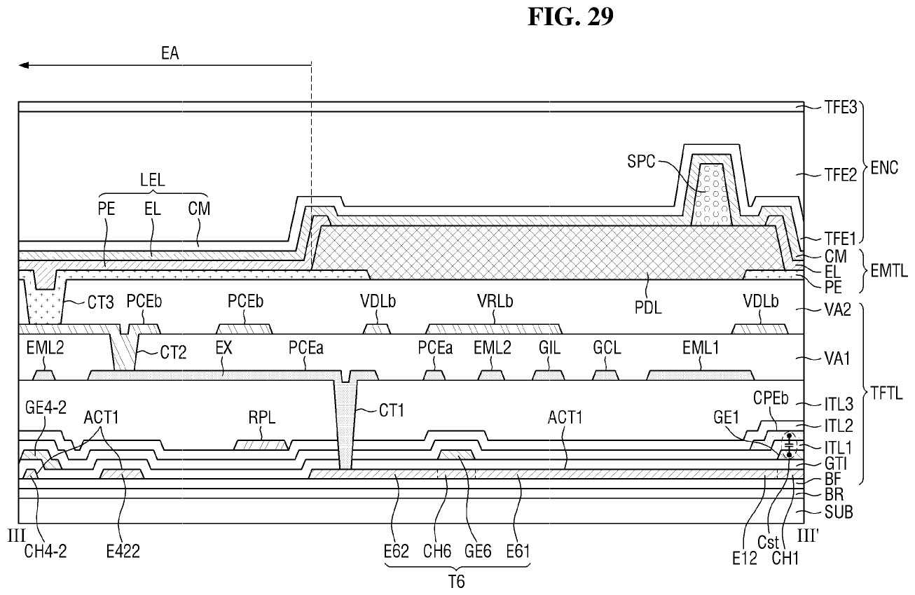

According to the present disclosure, the repair line RPL may be formed by the fourth pattern layer. In other words, according to the present disclosure, the repair line RPL may be formed in a pattern layer (e.g., the fourth pattern layer) other than the second pattern layer and the third pattern layer for forming the first capacitor Cst. In this case, since the repair line RPL included in the fourth pattern layer is disposed on a different layer from the sixth and fourth-second gate electrodes GE6 and GE4-2 included in the third pattern layer, a minimum distance between the repair short portion RSP of the repair line RPL and the sixth and fourth-second gate electrodes GE6 and GE4-2 in the second direction in a plan view may be further reduced. Similarly, since the repair line RPL included in the fourth pattern layer is disposed on a different layer from the seventh and eighth gate electrodes GE7 and GE8 included in the third pattern layer, the distance between the repair short portion RSP of the repair line RPL and the seventh and eighth gate electrodes GE7 and GE8 in the second direction in a plan view may be further reduced. Further, the thickness (e.g., 2500 Å) of the insulating layer (e.g., the first interlayer insulating layer ITL1 and the gate insulating layer GTI of FIG. 29) disposed between the fourth pattern layer (e.g., repair line RPL) and the third pattern layer (sixth and fourth-second gate electrodes GE6 and GE4-2) is thick, so that the minimum distance may be further reduced without affected by the laser during the repair process. As a result, the pixel size may be reduced, which may increase the resolution.

The fifth pattern layer may be disposed on the fourth pattern layer along the third direction DR3. An insulating layer may be disposed between the fourth pattern layer and the fifth pattern layer. As in the example shown in FIGS. 20, 24, and 26, the fifth pattern layer may include the second gate line GCL, the first gate line GWL, a lower reference voltage line VRLa, the data connection electrode DCE, the capacitor connection electrode CCE, the driving connection electrode VCE, the gate connection electrode GCE, the first emission control line EML1, the third gate line GIL, the second emission control line EML2, the lower pixel connection electrode PCEa, the first initialization voltage line VIL1, the fourth gate line EBL, the bias voltage line VBL, and the second initialization voltage line VIL2.

The second gate line GCL may, as shown in FIG. 26, be connected to the fifth-first gate electrode GE5-1, the fifth-second gate electrode GE5-2, the third-first gate electrode GE3-1, and the third-second gate electrode GE3-2 through the first type contact hole of the insulating layer.

The first gate line GWL may, as shown in FIG. 26, be connected to the second-first gate electrode GE2-1 and the second-second gate electrode GE2-2 through the first type contact hole of the insulating layer.

The lower reference voltage line VRLa may, as shown in FIG. 26, be connected to the second electrode E522 (e.g., second electrode E522 of the fifth-second transistor T5-2) of the second active layer ACT2 through the first type contact hole of the insulating layer.

The data connection electrode DCE may, as shown in FIG. 26, be connected to the second electrode E212 (e.g., second electrode E212 of the second-first transistor T2-1) of the second active layer ACT2 through the first type contact hole of the insulating layer.

The capacitor connection electrode CCE may, as shown in FIG. 26, be connected to the second electrodes E222 and E512 (e.g., the second electrode E212 of the second-second transistor T2-2 and the second electrode E512 of the fifth-first transistor T5-1) of the second active layer ACT2 through the first type contact hole of the insulating layer. Further, the capacitor connection electrode CCE may be connected to the lower capacitor electrode CPEa through the first type contact hole of the insulating layer and the hole 50 of the lower driving voltage line VDLa. Furthermore, the capacitor connection electrode CCE may be connected to the upper capacitor electrode CPEb through the first type contact hole of the insulating layer.

The driving connection electrode VCE may, as shown in FIG. 26, be connected to the lower driving voltage line VDLa through the first type contact hole of the insulating layer. Further, the driving connection electrode VCE may be connected to the first electrode E91 (e.g., first electrode E91 of the ninth transistor T9) of the first active layer ACT1 through the first type contact hole of the insulating layer. Furthermore, the driving connection electrode VCE may be connected to the third parasitic capacitor electrode PCPE3 through the first type contact hole of the insulating layer.

The gate connection electrode GCE may, as shown in FIG. 26, be connected to the first electrode E311 (e.g., first electrode E311 of the third-first transistor T3-1) of the first active layer ACT1 through the first type contact hole of the insulating layer. Further, the gate connection electrode GCE may be connected to the first gate electrode GE1 through the first type contact hole of the insulating layer and the hole 40 of the upper capacitor electrode CPEb.

The first emission control line EML1 may, as shown in FIG. 26, be connected to the ninth gate electrode GE9 through the first type contact hole of the insulating layer.

The third gate line GIL may, as shown in FIG. 26, be connected to the fourth-first gate electrode GE4-1 and the fourth-second gate electrode GE4-2 through the first type contact hole of the insulating layer.

The second emission control line EML2 may, as shown in FIG. 26, be connected to the sixth gate electrode GE6 through the first type contact hole of the insulating layer.

The lower pixel connection electrode PCEa may, as shown in FIG. 26, be connected to the second electrode E62 (e.g., second electrode E62 of the sixth transistor T6) of the first active layer ACT1 through the first type contact hole of the insulating layer.

The first initialization voltage line VIL1 may, as shown in FIG. 26, be connected to the first electrode E421 (e.g., first electrode E421 of the fourth-second transistor T4-2) of the first active layer ACT1 through the first type contact hole of the insulating layer.

The fourth gate line EBL may, as shown in FIG. 26, be connected to the seventh gate electrode GE7 and the eighth gate electrode GE8 through the first type contact hole of the insulating layer.

The bias voltage line VBL may transmit the bias voltage VB. The bias voltage line VBL may, as shown in FIG. 26, be connected to the second electrode E82 (e.g., second electrode E82 of the eighth transistor T8) of the first active layer ACT1 through the first type contact hole of the insulating layer.

The second initialization voltage line VIL2 may, as shown in FIG. 26, be connected to the second electrode E72 (e.g., second electrode E72 of the seventh transistor T7) of the first active layer ACT1, the first parasitic capacitor electrode PCPE1, and the second parasitic capacitor electrode PCPE2 through the first type contact hole of the insulating layer.

The sixth pattern layer may be disposed on the fifth pattern layer along the third direction DR3. An insulating layer may be disposed between the fifth pattern layer and the sixth pattern layer. As in the example shown in FIGS. 20, 25, and 27, the sixth pattern layer may include the data line DL, an upper driving voltage line VDLb, an upper pixel connection electrode PCEb, and an upper reference voltage line VRLb.

The data line DL may, as shown in FIG. 27, be connected to the data connection electrode DCE through the second type contact hole CTb of the insulating layer.

The driving voltage line VDL may, as shown in FIG. 27, be connected to the driving connection electrode VCE through the second type contact hole CTb of the insulating layer.

The upper pixel connection electrode PCEb may, as shown in FIG. 27, be connected to the lower pixel connection electrode PCEa through the second type contact hole of the insulating layer.

The upper reference voltage line VRLb may, as shown in FIG. 27, be connected to the lower reference voltage line VRLa through the second type contact hole of the insulating layer.

The seventh pattern layer may be disposed on the sixth pattern layer along the third direction DR3. An insulating layer may be disposed between the sixth pattern layer and the seventh pattern layer. As in the example shown in FIGS. 20 and 27, the seventh pattern layer may include the pixel electrode PE.

A part of the pixel electrode PE may be exposed by a bank which will be described later. For example, the bank may have an opening (hereinafter, emission area) through which a part of the pixel electrode PE is exposed. A light emitting layer may be disposed on the pixel electrode PE corresponding to the emission area.

The pixel electrode PE may be connected to the upper pixel connection electrode PCEb through the third type contact hole of the insulating layer.

FIG. 29 is a cross-sectional view taken along line III-III′ of FIG. 20.

As illustrated in FIG. 29, the display device 10 may include the substrate SUB, the barrier layer BR, the thin film transistor layer TFTL, the light emitting element layer EMTL, and the encapsulation layer ENC. The barrier layer BR, the thin film transistor layer TFTL, the light emitting element layer EMTL, and the encapsulation layer ENC may be sequentially disposed on the substrate SUB along the third direction DR3.

The substrate SUB of FIG. 29 may be the same as the substrate SUB of FIGS. 17 and 18 described above.

As shown in FIG. 29, the barrier layer BR may be disposed on the substrate SUB. The barrier layer BR of FIG. 29 may have the same material and structure as the barrier layer BR of FIGS. 17 and 18.

As shown in FIG. 29, the buffer layer BF may be disposed on the barrier layer BR. The buffer layer BF of FIG. 29 may have the same material and structure as the buffer layer BF of FIGS. 17 and 18.

The first pattern layer may be disposed on the buffer layer BF. For example, the first active layer ACT1 and the second active layer ACT2 may be disposed on the buffer layer BF. FIG. 29 illustrates an example in which the first active layer ACT1 is disposed on the buffer layer BF. The first active layer ACT1 may include the fourth-second channel region CH4-2 of the fourth-second transistor T4-2, the second electrode E422 of the fourth-second transistor T4-2, the second electrode E62 of the sixth transistor T6, the sixth channel region CH6 of the sixth transistor T6, the first electrode E61 of the sixth transistor T6, and the second electrode E12 of the first transistor T1.

The first pattern layer may have the same material and structure as the first pattern layer of FIGS. 17 and 18.

The gate insulating layer GTI may be disposed on the first pattern layer. For example, as shown in FIG. 29, the gate insulating layer GTI may be disposed on the first active layer ACT1. In this case, the gate insulating layer GTI may be disposed on the entire surface of the substrate SUB including the first active layer ACT1.

The gate insulating layer GTI of FIG. 29 may have the same material and structure as the gate insulating layer GTI of FIGS. 17 and 18.

The second pattern layer may be disposed on the gate insulating layer GTI. For example, the first gate electrode GE1, the second-first gate electrode GE2-1, the second-second gate electrode GE2-2, the third-first gate electrode GE3-1, the third-second gate electrode GE3-2, the fourth-first gate electrode GE4-1, the fourth-second gate electrode GE4-2, the fifth-first gate electrode GE5-1, the fifth-second gate electrode GE5-2, the sixth gate electrode GE6, the seventh gate electrode GE7, the eighth gate electrode GE8, the ninth gate electrode GE9, and the lower capacitor electrode CPEa may be disposed on the gate insulating layer GTI.

FIG. 29 illustrates an example in which the fourth-second gate electrode GE4-2, the sixth gate electrode GE6, and the first gate electrode GE1 are disposed on the gate insulating layer GTI.

The fourth-second gate electrode GE4-2 may be disposed on the gate insulating layer GTI to overlap the fourth-second channel region CH4-2 of the first active layer ACT1. The sixth gate electrode GE6 may be disposed on the gate insulating layer GTI to overlap the sixth channel region CH6 of the first active layer ACT1. The first gate electrode GE1 may be disposed on the gate insulating layer GTI to overlap the first channel region CH1 of the first active layer ACT1.

The second pattern layer of FIG. 29 may have the same material and structure as the above-described second pattern layer of FIGS. 17 and 18.

The first interlayer insulating layer ITL1 may be disposed on the second pattern layer. For example, as shown in FIG. 29, the first interlayer insulating layer ITL1 may be disposed on the fourth-second gate electrode GE4-2, the sixth gate electrode GE6, and the first gate electrode GE1. In this case, the first interlayer insulating layer ITL1 may be disposed on the entire surface of the substrate SUB including the fourth-second gate electrode GE4-2, the sixth gate electrode GE6, and the first gate electrode GE1.

The first interlayer insulating layer ITL1 of FIG. 29 may have the same material and structure as the first interlayer insulating layer ITL1 of FIGS. 17 and 18.

The third pattern layer may be disposed on the first interlayer insulating layer ITL1. For example, the first parasitic capacitor electrode PCPE1, the second parasitic capacitor electrode PCPE2, the third parasitic capacitor electrode PCPE3, the lower driving voltage line VDLa, and the upper capacitor electrode CPEb may be disposed on the first interlayer insulating layer ITL1. FIG. 29 illustrates an example in which the upper capacitor electrode CPEb is disposed on the first interlayer insulating layer ITL1. The upper capacitor electrode CPEb may be disposed on the first interlayer insulating layer ITL1 to overlap the first gate electrode GE1. The first capacitor Cst may be formed between the upper capacitor electrode CPEb and the first gate electrode GE1.

The third pattern layer of FIG. 29 may have the same material and structure as the third pattern layer of FIGS. 17 and 18.

The second interlayer insulating layer ITL2 may be disposed on the third pattern layer. For example, as shown in FIG. 29, the second interlayer insulating layer ITL2 may be disposed on the upper capacitor electrode CPEb. In this case, the second interlayer insulating layer ITL2 may be disposed on the entire surface of the substrate SUB including the upper capacitor electrode CPEb.

The second interlayer insulating layer ITL2 of FIG. 29 may have the same material and structure as the second interlayer insulating layer ITL2 of FIGS. 17 and 18.

The fourth pattern layer may be disposed on the second interlayer insulating layer ITL2. For example, the repair line RPL may be disposed on the second interlayer insulating layer ITL2.

The fourth pattern layer of FIG. 29 may have the same material and structure as the fourth pattern layer of FIGS. 17 and 18.

The third interlayer insulating layer ITL3 may be disposed on the fourth pattern layer. For example, as shown in FIG. 29, the third interlayer insulating layer ITL3 may be disposed on the repair line RPL. The third interlayer insulating layer ITL3 may be disposed on the entire surface of the substrate SUB including the repair line RPL.

The third interlayer insulating layer ITL3 of FIG. 29 may have the same material and structure as the third interlayer insulating layer ITL3 of FIGS. 17 and 18.

The fifth pattern layer may be disposed on the third interlayer insulating layer ITL3. For example, the second gate line GCL, the first gate line GWL, the lower reference voltage line VRLa, the data connection electrode DCE, the capacitor connection electrode CCE, the driving connection electrode VCE, the gate connection electrode GCE, the first emission control line EML1, the third gate line GIL, the second emission control line EML2, the lower pixel connection electrode PCEa, the first initialization voltage line VIL1, the fourth gate line EBL, the bias voltage line VBL, and the second initialization voltage line VIL2 may be disposed on the third interlayer insulating layer ITL3. FIG. 29 illustrates an example in which the second emission control line EML2, the lower pixel connection electrode PCEa, the third gate line GIL, the second gate line GCL, and the first emission control line EML1 are disposed on the third interlayer insulating layer ITL3.

The lower pixel connection electrode PCEa may be connected to the second electrode E62 of the sixth transistor T6 through a first contact hole CT1 penetrating the third interlayer insulating layer ITL3, the second interlayer insulating layer ITL2, the first interlayer insulating layer ITL1, and the gate insulating layer GTI.

The first contact hole CT1 may belong to the first type contact hole CTa.

The fifth pattern layer of FIG. 29 may have the same material and structure as the fifth pattern layer of FIGS. 17 and 18.

The first planarization layer VA1 may be disposed on the fifth pattern layer. For example, the first planarization layer VA1 may be disposed on the second emission control line EML2, the lower pixel connection electrode PCEa, the third gate line GIL, the second gate line GCL, and the first emission control line EML1. The first planarization layer VA1 may be disposed on the entire surface of the substrate SUB including the second emission control line EML2, the lower pixel connection electrode PCEa, the third gate line GIL, the second gate line GCL, and the first emission control line EML1.

The first planarization layer VA1 of FIG. 29 may have the same material and structure as the first planarization layer VA1 of FIGS. 17 and 18.

The sixth pattern layer may be disposed on the first planarization layer VA1. For example, as shown in FIG. 29, the upper driving voltage line VDLb, the upper pixel connection electrode PCEb, and the upper reference voltage line VRLb may be disposed on the first planarization layer VA1.

The upper pixel connection electrode PCEb may be connected to the lower pixel connection electrode PCEa through a second contact hole CT2 penetrating the first planarization layer VA1.

The aforementioned second contact hole CT2 may belong to the second type contact hole CTb.

The sixth pattern layer of FIG. 29 may have the same material and structure as the sixth pattern layer of FIGS. 17 and 18.

A second planarization layer VA2 may be disposed on the sixth pattern layer. For example, the second planarization layer VA2 may be disposed on the upper driving voltage line VDLb, the upper pixel connection electrode PCEb, and the upper reference voltage line VRLb. The second planarization layer VA2 may be disposed on the entire surface of the substrate SUB including the upper driving voltage line VDLb, the upper pixel connection electrode PCEb, and the upper reference voltage line VRLb.

The second planarization layer VA2 of FIG. 29 may have the same material and structure as the second planarization layer VA2 of FIGS. 17 and 18.

The seventh pattern layer may be disposed on the second planarization layer VA2. For example, as shown in FIG. 29, the light emitting element layer EMTL including the seventh pattern layer may be disposed on the second planarization layer VA2. For example, the pixel electrode PE as the seventh pattern layer may be disposed on the second planarization layer VA2.

The pixel electrode PE may be connected to the upper pixel connection electrode PCEb through the third contact hole CT3 penetrating the second planarization layer VA2.

The aforementioned third contact hole CT3 may belong to the third type contact hole CTc.

In addition to the aforementioned seventh pattern layer, the above-described light emitting element layer EMTL may further include the light emitting element LEL and the bank PDL (or pixel defining layer).

The light emitting element LEL may include the pixel electrode PE, the light emitting layer EL, and the common electrode CM. The emission area EA, in which the pixel electrode PE, the light emitting layer EL, and the common electrode CM are sequentially stacked, indicates an area in which holes from the pixel electrode PE and electrons from the common electrode CM are combined with each other in the light emitting layer to emit light. In this case, the pixel electrode PE may be the anode electrode of the light emitting element LEL, and the common electrode CM may be the cathode electrode of the light emitting element LEL.

Since the light emitting element LEL, spacer SPC, and encapsulation layer ENC of FIG. 29 are the same as the light emitting element LEL, spacer SPC, and encapsulation layer ENC of FIGS. 17 and 18 described above, respectively, the description of the light emitting element LEL, spacer SPC, and encapsulation layer ENC of FIG. 29 refers to the description of FIGS. 17 and 18.

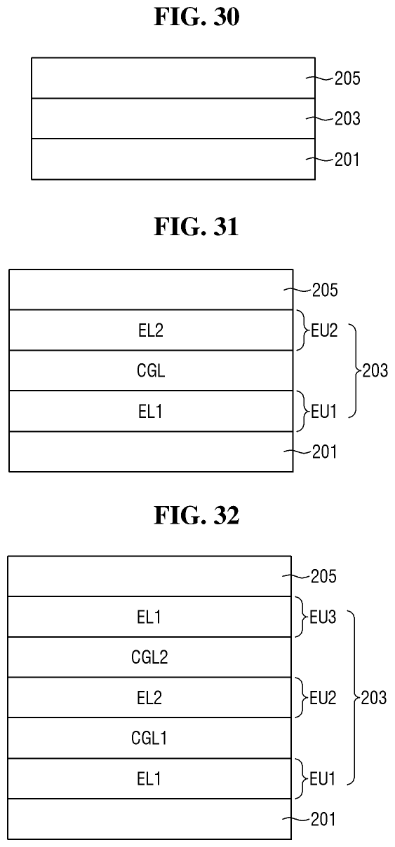

Meanwhile, another structure of the light emitting element LEL (e.g., LEL of FIGS. 17 and 29) will be described with reference to FIGS. 30 to 37.

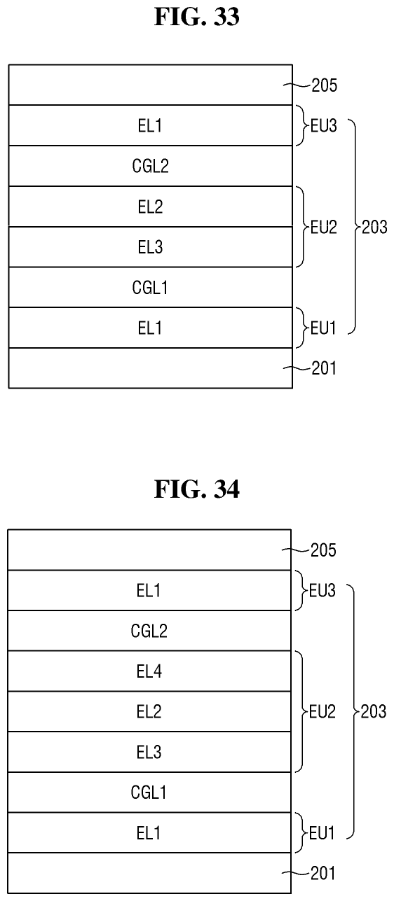

FIG. 30 is a cross-sectional view illustrating a structure of a display element according to one embodiment, and FIGS. 31 to 34 are cross-sectional views illustrating a structure of the light emitting element LEL according to one embodiment.

Referring to FIG. 30, the light emitting element LEL (e.g., an organic light emitting diode) according to one embodiment may include a pixel electrode 201, a common electrode 205, and an intermediate layer 203 disposed between the pixel electrode 201 and the common electrode 205 described above.

The pixel electrode 201 may include a light-transmitting conductive oxide such as indium tin oxide (ITO), indium zinc oxide (IZO), zinc oxide (ZnO), indium oxide (In₂O₃), indium gallium oxide (IGO), or aluminum zinc oxide (AZO). The pixel electrode 201 may include a reflective layer containing silver (Ag), magnesium (Mg), aluminum (Al), platinum (Pt), palladium (Pd), gold (Au), nickel (Ni), neodymium (Nd), iridium (Ir), chromium (Cr) or a compound thereof. For example, the pixel electrode 201 may have a three-layer structure of ITO/Ag/ITO.

The common electrode 205 may be disposed on the intermediate layer 203. The common electrode 205 may include a low work function metal, an alloy, an electrically conductive compound, or any combination thereof. For example, the common electrode 205 may include lithium (Li), silver (Ag), magnesium (Mg), aluminum (Al), aluminum-lithium (Al—Li), calcium (Ca), magnesium-indium (Mg—In), magnesium-silver (Mg—Ag), ytterbium (Yb), silver-ytterbium (Ag—Yb), ITO, IZO, or any combination thereof. The common electrode 205 may be a transmissive electrode, a semi-transmissive electrode, or a reflective electrode.

The intermediate layer 203 may include a high molecular material or a low molecular material that emits light of a predetermined color. In addition to various organic materials, the intermediate layer 203 may further include metal-containing compounds such as organometallic compounds, inorganic materials such as quantum dots, and the like. In one embodiment, the intermediate layer 203 may include one light emitting layer and a first functional layer and a second functional layer respectively disposed below and above the one light emitting layer. The first functional layer may include, for example, a hole transport layer HTL or may include the hole transport layer and a hole injection layer HIL. The second functional layer is a component disposed on the light emitting layer and is optional. For example, the intermediate layer 203 may include or may not include the second functional layer. The second functional layer may include an electron transport layer ETL and/or an electron injection layer EIL.

In one embodiment, the intermediate layer 203 may include two or more emitting units that are sequentially stacked between the pixel electrode 201 and the common electrode 205, and a charge generation layer CGL disposed between the two emitting units. When the intermediate layer 203 includes an emitting unit and a charge generation layer, the light emitting element LEL (e.g., an organic light emitting diode) may be a tandem light emitting element. The light emitting element LEL (e.g., an organic light emitting diode) may improve color purity and luminous efficiency by having a stacked structure of a plurality of emitting units.

One emitting unit may include a light emitting layer and a first functional layer and a second functional layer respectively disposed below and above the light emitting layer. The charge generation layer CGL may include a negative charge generation layer and a positive charge generation layer. The luminous efficiency of an organic light emitting diode, which is a tandem light emitting element having a plurality of light emitting layers, may be further increased by the negative charge generation layer and the positive charge generation layer.

The negative charge generation layer may be an n-type charge generation layer. The negative charge generation layer may supply electrons. The negative charge generation layer may include a host and a dopant. The host may include an organic material. The dopant may include a metal material. The positive charge generation layer may be a p-type charge generation layer. The positive charge generation layer may supply holes. The positive charge generation layer may include a host and a dopant. The host may include an organic material. The dopant may include a metal material.

In one embodiment, as illustrated in FIG. 31, the light emitting element LEL (e.g., an organic light emitting diode) may include a first emitting unit EU1 including a first light emitting layer EL1 and a second emitting unit EU2 including a second light emitting layer EL2 that are sequentially stacked. The charge generation layer CGL may be disposed between the first emitting unit EU1 and the second emitting unit EU2. For example, the light emitting element LEL (e.g., an organic light emitting diode) may include the pixel electrode 201, the first light emitting layer EL1, the charge generation layer CGL, the second light emitting layer EL2, and the common electrode 205 that are sequentially stacked. The first functional layer and the second functional layer may be disposed on and under the first light emitting layer EL1, respectively. The first functional layer and the second functional layer may be included below and above the second light emitting layer EL2, respectively. The first light emitting layer EL1 may be a blue light emitting layer, and the second light emitting layer EL2 may be a yellow light emitting layer.

In one embodiment, as illustrated in FIG. 32, the light emitting element LEL (e.g., an organic light emitting diode) may include the first emitting unit EU1 and the third emitting unit EU3 including the first light emitting layer EL1, and the second emitting unit EU2 including the second light emitting layer EL2. The first charge generation layer CGL1 may be disposed between the first emitting unit EU1 and the second emitting unit EU2, and the second charge generation layer CGL2 may be disposed between the second emitting unit EU2 and the third emitting unit EU3. For example, the light emitting element LEL (e.g., an organic light emitting diode) may include the pixel electrode 201, the first light emitting layer EL1, the first charge generation layer CGL1, the second light emitting layer EL2, the second charge generation layer CGL2, the first light emitting layer EL1, and the common electrode 205 that are sequentially stacked. The first functional layer and the second functional layer may be disposed on and under the first light emitting layer EL1, respectively. The first functional layer and the second functional layer may be disposed on and below the second light emitting layer EL2, respectively. The first light emitting layer EL1 may be a blue light emitting layer, and the second light emitting layer EL2 may be a yellow light emitting layer.

In one embodiment, in the light emitting element LEL (e.g., an organic light emitting diode), the second emitting unit EU2 may further include a third light emitting layer EL3 and/or a fourth light emitting layer EL4 in direct contact with the second light emitting layer EL2 below and/or above the second light emitting layer EL2, in addition to the second light emitting layer EL2. Here, direct contact may mean that no other layer is disposed between the second light emitting layer EL2 and the third light emitting layer EL3 and/or between the second light emitting layer EL2 and the fourth light emitting layer EL4. The third light emitting layer EL3 may be a red light emitting layer, and the fourth light emitting layer EL4 may be a green light emitting layer.

For example, as illustrated in FIG. 33, the light emitting element LEL (e.g., an organic light emitting diode) may include the pixel electrode 201, the first light emitting layer EL1, the first charge generation layer CGL1, the third light emitting layer EL3, the second light emitting layer EL2, the second charge generation layer CGL2, the first light emitting layer EL1, and the common electrode 205 that are sequentially stacked. Alternatively, as illustrated in FIG. 31, the light emitting element LEL (e.g., an organic light emitting diode) may include the pixel electrode 201, the first light emitting layer EL1, the first charge generation layer CGL1, the third light emitting layer EL3, the second light emitting layer EL2, the fourth light emitting layer ELA, the second charge generation layer CGL2, the first light emitting layer EL1, and the common electrode 205 that are sequentially stacked.

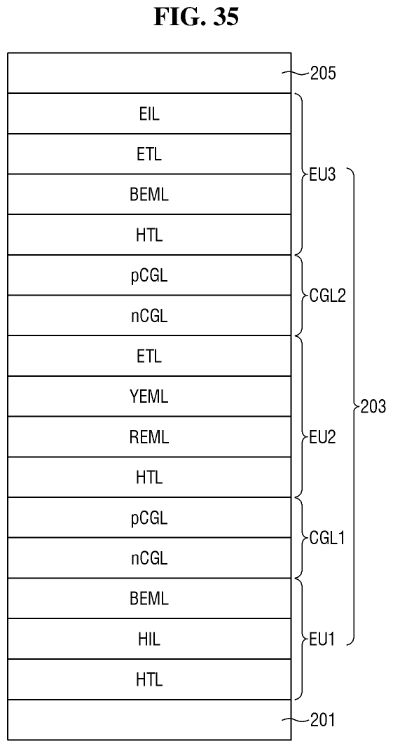

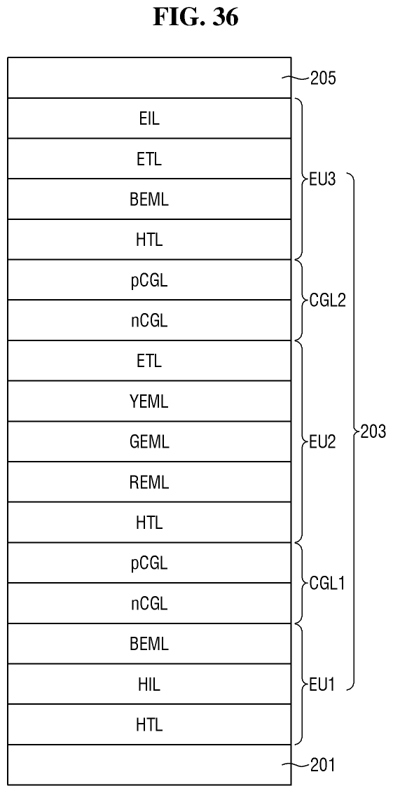

FIG. 35 is a cross-sectional view illustrating an example of the organic light emitting diode of FIG. 33, and FIG. 36 is a cross-sectional view illustrating an example of the organic light emitting diode of FIG. 34.

Referring to FIG. 35, the light emitting element LEL (e.g., an organic light emitting diode) may include the first emitting unit EU1, the second emitting unit EU2, and the third emitting unit EU3 that are sequentially stacked. The first charge generation layer CGL1 may be disposed between the first emitting unit EU1 and the second emitting unit EU2, and the second charge generation layer CGL2 may be disposed between the second emitting unit EU2 and the third emitting unit EU3. The first charge generation layer CGL1 and the second charge generation layer CGL2 may include a negative charge generation layer nCGL and a positive charge generation layer pCGL, respectively.

The first emitting unit EU1 may include a blue light emitting layer BEML. The first emitting unit EU1 may further include the hole injection layer HIL and the hole transport layer HTL between the pixel electrode 201 and the blue light emitting layer BEML. In one embodiment, a p-doped layer may be further included between the hole injection layer HIL and the hole transport layer HTL. The P-doped layer may be formed by doping the hole injection layer HIL with a p-type doping material. In one embodiment, at least one of a blue light auxiliary layer, an electron blocking layer, or a buffer layer may be further included between the blue light emitting layer BEML and the hole transport layer HTL. The blue light auxiliary layer may increase light emission efficiency of the blue light emitting layer BEML. The blue light auxiliary layer may increase light emission efficiency of the blue light emitting layer BEML by adjusting hole charge balance. The electron blocking layer may prevent electron injection into the hole transport layer HTL. The buffer layer may compensate for a resonance distance according to a wavelength of light emitted from the light emitting layer.

The second emitting unit EU2 may include a yellow light emitting layer YEML and a red light emitting layer REML in direct contact with the yellow light emitting layer YEML below the yellow light emitting layer YEML. The second emitting unit EU2 may further include the hole transport layer HTL between the positive charge generation layer pCGL of the first charge generation layer CGL1 and the red light emitting layer REML, and may further include the electron transport layer ETL between the yellow light emitting layer YEML and the negative charge generation layer nCGL of the second charge generation layer CGL2.

The third emitting unit EU3 may include the blue light emitting layer BEML. The third emitting unit EU3 may further include the hole transport layer HTL between the positive charge generation layer pCGL of the second charge generation layer CGL2 and the blue light emitting layer BEML. The third emitting unit EU3 may further include the electron transport layer ETL and the electron injection layer EIL between the blue light emitting layer BEML and the common electrode 205. The electron transport layer ETL may have a single layer or a multilayer. In one embodiment, at least one of a blue light auxiliary layer, an electron blocking layer, or a buffer layer may be further included between the blue light emitting layer BEML and the hole transport layer HTL. At least one of a hole blocking layer or a buffer layer may be further included between the blue light emitting layer BEML and the electron transport layer ETL. The hole blocking layer may prevent hole injection into the electron transport layer ETL.

The light emitting element LEL (e.g., an organic light emitting diode) illustrated in FIG. 36 is different from the light emitting element LEL (e.g., an organic light emitting diode) illustrated in FIG. 34 in the stacked structure of the second emitting unit EU2, and other configurations are the same. Referring to FIG. 36, the second emitting unit EU2 may include the yellow light emitting layer YEML, the green light emitting layer GEML in direct contact with the yellow light emitting layer YEML below the yellow light emitting layer YEML, and the electron transport layer ETL in direct contact with the yellow light emitting layer YEML above the yellow light emitting layer YEML. The second emitting unit EU2 may further include the hole transport layer HTL between the positive charge generation layer pCGL of the first charge generation layer CGL1 and the red light emitting layer REML, and may further include the electron transport layer ETL between the green light emitting layer GEML and the negative charge generation layer nCGL of the second charge generation layer CGL2.

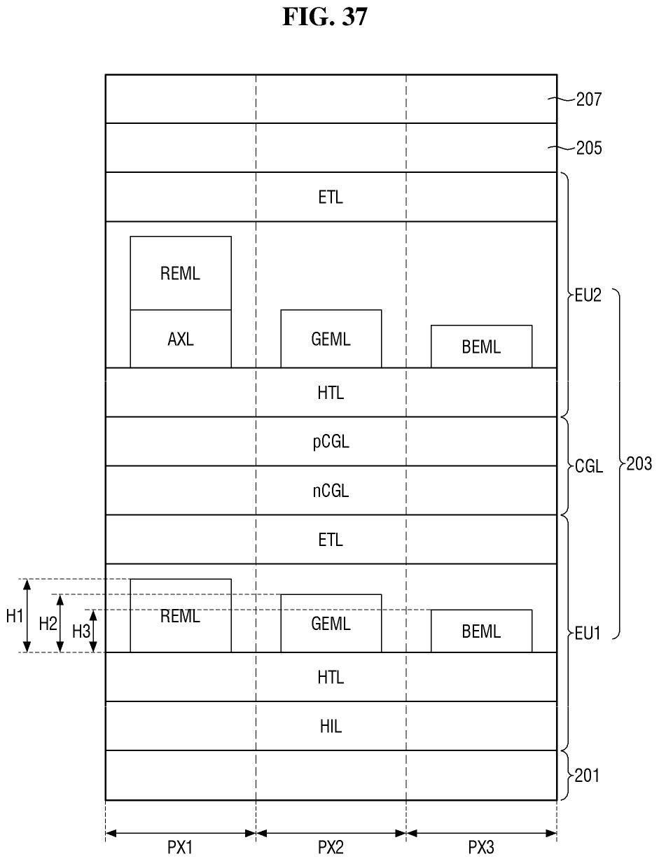

FIG. 37 is a cross-sectional view illustrating a structure of a pixel of a display device according to one embodiment.

Referring to FIG. 37, the display panel 100 of the display device 10 may include a plurality of pixels (e.g., the sub-pixels described above). The plurality of pixels may include the first pixel PX1, the second pixel PX2, and the third pixel PX3. Each of the first pixel PX1, the second pixel PX2, and the third pixel PX3 may include the pixel electrode 201, the common electrode 205, and the intermediate layer 203. In one embodiment, the first pixel PX1 may be a red pixel, the second pixel PX2 may be a green pixel, and the third pixel PX3 may be a blue pixel.

The pixel electrode 201 may be independently provided in each of the first pixel PX1, the second pixel PX2, and the third pixel PX3.

The intermediate layer 203 of each of the first pixel PX1, the second pixel PX2, and the third pixel PX3 may include the first emitting unit EU1 and the second emitting unit EU2 that are sequentially stacked, and the charge generation layer CGL between the first emitting unit EU1 and the second emitting unit EU2. The charge generation layer CGL may include the negative charge generation layer nCGL and the positive charge generation layer pCGL. The charge generation layer CGL may be a common layer continuously formed in the first pixel PX1, the second pixel PX2, and the third pixel PX3.

The first emitting unit EU1 of the first pixel PX1 may include the hole injection layer HIL, the hole transport layer HTL, the red light emitting layer REML, and the electron transport layer ETL that are sequentially stacked on the pixel electrode 201. The first emitting unit EU1 of the second pixel PX2 may include the hole injection layer HIL, the hole transport layer HTL, the green light emitting layer GEML, and the electron transport layer ETL that are sequentially stacked on the pixel electrode 201. The first emitting unit EU1 of the third pixel PX3 may include the hole injection layer HIL, the hole transport layer HTL, the blue light emitting layer BEML, and the electron transport layer ETL that are sequentially stacked on the pixel electrode 201. Each of the hole injection layer HIL, the hole transport layer HTL, and the electron transport layer ETL of the first emitting unit EU1 may be a common layer continuously formed in the first pixel PX1, the second pixel PX2, and the third pixel PX3.

The second emitting unit EU2 of the first pixel PX1 may include the hole transport layer HTL, an auxiliary layer AXL, the red light emitting layer REML, and the electron transport layer ETL that are sequentially stacked on the charge generation layer CGL. The second emitting unit EU2 of the second pixel PX2 may include the hole transport layer HTL, the green light emitting layer GEML, and the electron transport layer ETL that are sequentially stacked on the charge generation layer CGL. The second emitting unit EU2 of the third pixel PX3 may include the hole transport layer HTL, the blue light emitting layer BEML, and the electron transport layer ETL that are sequentially stacked on the charge generation layer CGL. Each of the hole transport layer HTL and the electron transport layer ETL of the second emitting unit EU2 may be a common layer continuously formed in the first pixel PX1, the second pixel PX2, and the third pixel PX3. In one embodiment, at least one of a hole blocking layer or a buffer layer may be further included between the light emitting layer and the electron transport layer ETL in the second emitting unit EU2 of the first pixel PX1, the second pixel PX2, and the third pixel PX3.

A thickness H1 of the red light emitting layer REML, a thickness H2 of the green light emitting layer GEML, and a thickness H3 of the blue light emitting layer BEML may be determined according to the resonance distance. The auxiliary layer AXL may be a layer added to adjust the resonance distance, and may include a resonance auxiliary material. For example, the auxiliary layer AXL may include the same material as the hole transport layer HTL.

In FIG. 37, the auxiliary layer AXL may be disposed only in the first pixel PX1, but the embodiment of the present disclosure is not limited thereto. For example, the auxiliary layer AXL may be disposed in at least one of the first pixel PX1, the second pixel PX2, or the third pixel PX3 to adjust the resonance distance of each of the first pixel PX1, the second pixel PX2, and the third pixel PX3.

The display panel of the display device 10 may further include a capping layer 207 disposed outside the common electrode 205. The capping layer 207 may serve to improve luminous efficiency by the principle of constructive interference. Accordingly, the light extraction efficiency of the light emitting element LEL (e.g., an organic light emitting diode) may be increased, so that the luminous efficiency of the light emitting element LEL (e.g., an organic light emitting diode) may be improved.

In concluding the detailed description, those skilled in the art will appreciate that many variations and modifications can be made to the preferred embodiments without substantially departing from the principles of the present inventive concept. Therefore, the disclosed preferred embodiments of the inventive concept are used in a generic and descriptive sense only and not for purposes of limitation.

What is claimed is:

1. A display device comprising:
a substrate;
a first gate electrode disposed on the substrate;
a lower capacitor electrode disposed on the first gate electrode to overlap the first gate electrode in a plan view; and
a repair line disposed on the lower capacitor electrode.

2. The display device of claim 1, further comprising an upper capacitor electrode disposed on the lower capacitor electrode to overlap the lower capacitor electrode in a plan view.

3. The display device of claim 2, wherein the first gate electrode overlaps the upper capacitor electrode in a plan view.

4. The display device of claim 2, wherein an area of the lower capacitor electrode is greater than an area of the first gate electrode in a plan view.

5. The display device of claim 2, wherein an area of the upper capacitor electrode is greater than the area of the lower capacitor electrode in a plan view.

6. The display device of claim 2, further comprising a driving voltage line connected to the area of the upper capacitor electrode.

7. The display device of claim 2, wherein the repair line and the upper capacitor electrode are disposed on the same layer.

8. The display device of claim 2, wherein a second capacitor is disposed in an overlapping region between the lower capacitor electrode and the upper capacitor electrode.

9. The display device of claim 2, wherein the upper capacitor electrode has a larger number of holes than the lower capacitor electrode.

10. The display device of claim 9, wherein one of the holes in the upper capacitor electrode overlaps a hole in the lower capacitor electrode in a plan view.

11. The display device of claim 10, further comprising a second gate electrode and a third gate electrode disposed on the same layer as the first gate electrode.

12. The display device of claim 1, wherein a first capacitor is disposed in an overlapping region between the first gate electrode and the lower capacitor electrode.

13. The display device of claim 1, further comprising a second gate electrode disposed adjacent to the first gate electrode,
wherein the repair line is disposed between the first gate electrode and the second gate electrode in a plan view.

14. The display device of claim 1, further comprising a pixel connection electrode overlapping the repair line.

15. The display device of claim 14, wherein the repair line comprises a repair short portion overlapping the pixel connection electrode.

16. A display device comprising:
a substrate;
a first transistor including a first gate electrode disposed on the substrate;
a lower capacitor electrode disposed on the first gate electrode to overlap the first gate electrode in a plan view;
an upper capacitor electrode disposed on the lower capacitor electrode to overlap the lower capacitor electrode in a plan view;
a repair line disposed on a same plane as the upper capacitor electrode; and
a pixel electrode disposed on the repair line to overlap the repair line.

17. The display device of claim 16, wherein the first gate electrode and the lower capacitor electrode constitute a first capacitor, and the lower capacitor electrode and the upper capacitor electrode constitute a second capacitor.

18. The display device of claim 17, wherein the first capacitor and the second capacitor are serially connected between the first gate electrode and a driving voltage line.

19. The display device of claim 18, wherein the pixel electrode includes a pixel connection electrode connected to the first transistor, and wherein the repair line overlaps the pixel connection electrode.

20. The display device of claim 19, further comprising a second transistor including a second gate electrode disposed adjacent to the first gate electrode,
wherein the repair line is disposed between the first gate electrode and the second gate electrode not to overlap the first gate electrode and the second gate electrode in a plan view.
